(19) United States
(12) Patent Application Publication
(10) Pub. No.: US 2026/0157016 A1
(43) Pub. Date: Jun. 4, 2026

(54) SYSTEM, DEVICE, AND METHOD FOR RADIATION HARDNESS OF ORGANIC SEMICONDUCTORS AND PHOTOVOLTAIC DEVICES

(71) Applicant: The Regents of the University of Michigan, Ann Arbor, MI (US)

(72) Inventors: Yongxi Li, Ann Arbor, MI (US); Stephen R. Forrest, Ann Arbor, MI (US)

(21) Appl. No.: 19/405,819

(22) Filed: Dec. 2, 2025

Related U.S. Application Data
(60) Provisional application No. 63/727,425, filed on Dec. 3, 2024.

(51) Int. Cl. H10K 30/30; H10K 30/57

(52) U.S. Cl. CPC H10K 30/30; H10K 30/57

(57) ABSTRACT

Provided are small molecules for organic photovoltaic cells lacking pendant aliphatic groups with labile hydrogens. Small-molecule OPVs grown by vacuum thermal evaporation are resistant to degradation by 30 keV proton irradiation, in contrast to polymer-based OPVs that suffer a 50% efficiency loss under similar conditions. Also provided are formulations comprising these compounds. Further provided are optoelectronic devices that utilize these compounds.

### CROSS-REFERENCE TO RELATED APPLICATIONS

The present application claims priority to U.S. Provisional Application No. 63/727,425, filed Dec. 3, 2024, which is incorporated by reference herein in its entirety.

### BACKGROUND

Optoelectronic devices rely on the optical and electronic properties of materials to either produce or detect electromagnetic radiation electronically or to generate electricity from ambient electromagnetic radiation. Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors.

Organic photovoltaic cells (OPVs) have sparked considerable interest in recent years owing to their flexibility, light weight, non-toxic nature and semi-transparency that makes them ideal for building integrated and building applied applications. Compared to the commercial solar modules that typically have power conversion efficiencies of PCE=15-22% of sunlight, organics have improved from 10% in 2016 to over 17% in 2019 for single junction devices. Advances have steadily continued, headed toward single junction thermodynamically limited efficiencies of ˜25%, with potentially higher efficiencies based on multijunction cells. This rapid advance has been paced by the development of non-fullerene acceptors (NFAs).

Lightweight, mechanically and radiation resilient solar power sources are essential for space-borne platforms such as satellites, propulsion and powering of autonomous vehicles, robots, and space suits. Organic photovoltaic (OPV) cells are highly promising as a solution for this sector due to their combination of features of ultralightweight, high power conversion efficiency (PCE), flexibility that allows for compact stowage, and exceptional stability when used for terrestrial applications. The continuous advancement of organic materials has enabled the PCE of OPVs to exceed 20%, making them competitive with other thin film photovoltaic technologies.

There is a need in the art for radiation resilient organic photovoltaic devices. The present invention satisfies this need.

### SUMMARY OF THE DISCLOSURE

In one aspect, the present disclosure relates to a compound of Formula I, Formula II, Formula III, or Formula IV:

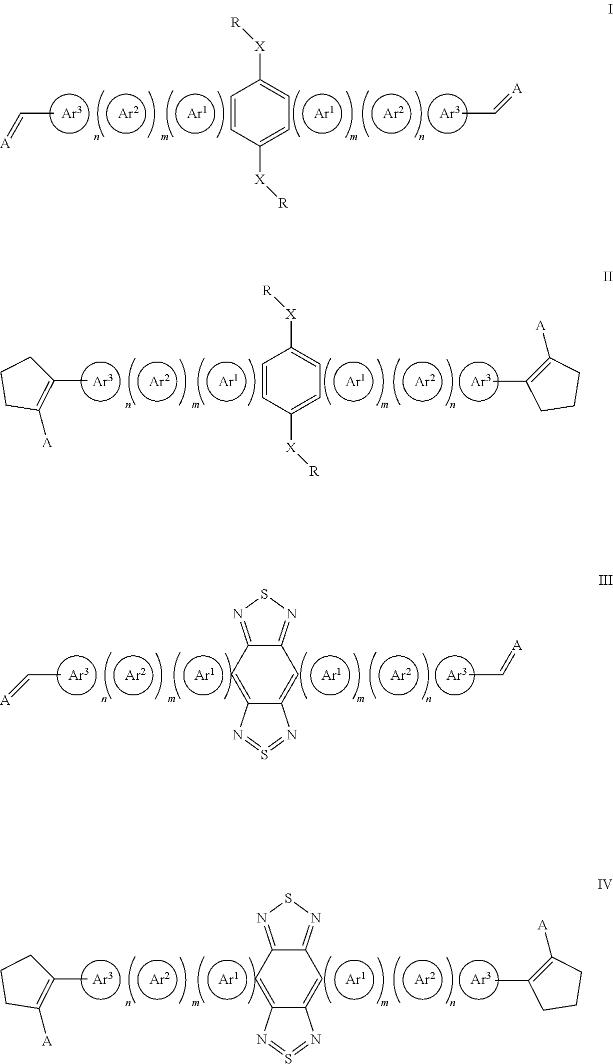

wherein:
Ar¹ is an aromatic group, which is conjugated, fused, or connected to a benzene ring and is selected from the group consisting of:

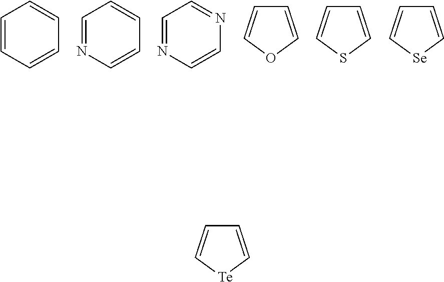

Ar² is an aromatic group, which is conjugated, fused, or connected to an Ar¹ ring, and is selected from the group consisting of:

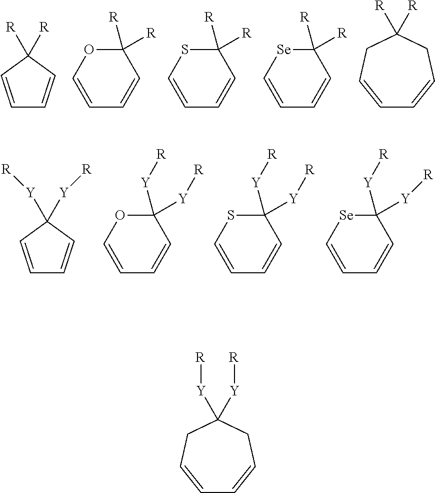

Ar³ is an aromatic group, which is conjugated, fused, or connected to an Ar² ring, is selected from the group consisting of:

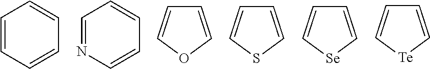

each X is independently selected from the group consisting of oxygen, sulfur, selenium, and nitrogen;
each R is independently an aromatic group;
m is from 0 to 10; and
n is from 0 to 10;
A is one of the following structures:

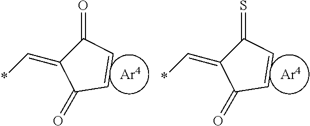 [SMILES: *C=C1C(=O)C=CC1=O ; */C=C1\C(=O)C=CC1=S]

Ar⁴ is an aromatic group, which is conjugated fused connected to an adjacent ring, and is selected from the group consisting of:

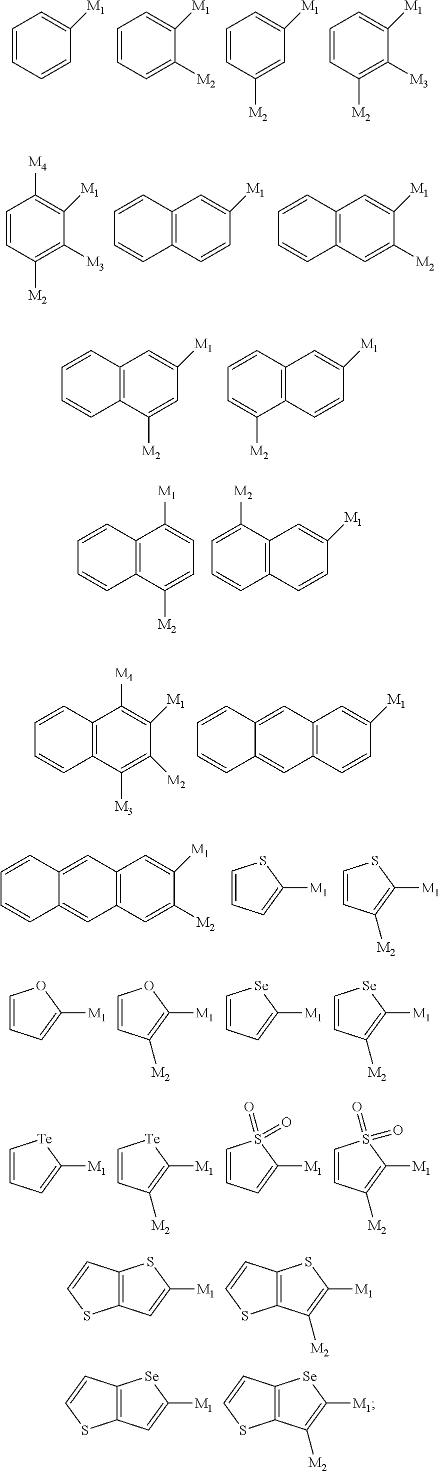

and
each M₁, M₂, M₃, and M₄ is independently selected from the group consisting of hydrogen, fluorine, chlorine, bromine, iodine, and cyano group, wherein at least one of M₁, M₂, M₃, and M₄ is a halogen.

In another aspect, the present disclosure provides a formulation comprising a compound of Formula I as described herein.

In yet another aspect, the present disclosure provides an optoelectronic device comprising a compound of Formula I as described herein.

### BRIEF DESCRIPTION OF THE DRAWINGS

For a more complete understanding of the disclosure, reference is made to the following detailed description and accompanying drawing figures, in which like reference numerals may be used to identify like elements in the figures.

FIG. 1 depicts an exemplary single-junction photovoltaic cell.

FIG. 2 depicts an exemplary tandem photovoltaic cell.

FIG. 3 depicts an exemplary photovoltaic cell.

FIG. 4 depicts trajectory of protons in the solar cell organic photoactive layers using the software SRIM (Stopping and Range of Ions in Matter). Penetration of protons with energies 10, 30, 100 keV and 1 MeV incident on the metal electrode side of the device are depicted.

FIG. 5 is a plot of the SRIM results. The 30 keV protons are most effective in creating a uniform damage profile throughout the thin BHJ due to their extensive interaction with the organic materials.

FIG. 6 depicts known structures used in organic photovoltaic cells.

FIG. 7 is a J-V plot showing the effect of radiation on VTE-deposited small molecule OPVs.

FIG. 8 a plot of EQE vs wavelength showing the effect of radiation on VTE-deposited small molecule OPVs. VTE-deposited small molecule OPVs exhibited significantly improved tolerance to proton radiation such that their initial performance remained largely unchanged with remaining factor of PCE of ˜100%.

FIG. 9 is a J-V plot showing the effect of radiation on solution-deposited polymer-based PCE-10:BT-CIC, and PM6:Y6 cells.

FIG. 10 is a plot of EQE vs wavelength for solution-deposited polymer-based PCE-10:BT-CIC, and PM6:Y6 cells. Upon the proton irradiation at a fluence of 10¹² cm⁻², both polymer-based PCE-10:BT-CIC, and PM6:Y6 cells exhibit rapid degradation. The remaining performance reduced to 36% for the PCE-10:BT-CIC cells and 50% for the PM6:Y6 cells, respectively.

FIG. 11 is a J-V plot showing the recovery in device characteristics observed in proton-irradiated PM6:Y6 OPVs after heating to 85±1° C. for 21 h.

FIG. 12 is an EQE plot showing the recovery in device characteristics observed in proton-irradiated PM6:Y6 OPVs after heating to 85±1° C. for 21 h. After annealing, the performance of the irradiated device is largely restored, with the PCE reaching nearly 90% of its value before irradiation. While the short circuit current density (J_{SC}) fully recovers, there was a 5% reduction in open-circuit voltage (V_{OC}) and a 10% reduction in fill factor (FF).

FIG. 13 shows J_{SC}, V_{OC}, FF, and PCE as functions of annealing time at temperatures of 45±1° C., 65±1° C., and 85±1° C. in a N₂ filled glove box. Compared to the temperatures of 65±1° C. and 85±1° C., where the PCE recovers by approximately 90% of the non-irradiated value after 93 h, at 45±1° C. only 70% of the efficiency was restored. Moreover, the thermally annealed PM6:Y6 device were exposed to a second round of proton radiation with the same 30 keV fluence, followed by thermal annealing at same conditions as before.

FIG. 14 is gel permeation chromatography (GPC) trace showing that the polymer underwent cross-linking as a result of exposure to proton irradiation (noting that, in a GPC trace, higher MW compounds are generally eluted first).

FIG. 15 depicts absorbance spectra of irradiated and fresh polymer and small molecule absorbers. PCE-10 retains its light absorption properties even after washing with chlorobenzene, a solvent that usually dissolves PCE-10. This behavior points to decreased solubility due to the formation of crosslinked polymer networks. The absorption of PCE-10 is unaffected by irradiation.

FIG. 16 further depicts absorbance and emission spectra of PM6 and PCE-10. Notably, the absorption and photoluminescence (PL) spectra of the PCE-10 and PM6 are unaffected by irradiation.

FIG. 17 is a plot of further SRIM studies. H atoms (Magenta) are displaced in the BHJ by 30 keV protons, resulting in de-protonation.

FIG. 18 depicts formation of radicals by solar radiation. De-protonation leads to the formation of a free radical defect, or H vacancy, where a carbon atom in the alkyl chain, which was previously fourfold coordinated, now has two C—C bonds and one C—H bond. It is likely that the resulting radical formation may promote polymer cross-linking, thereby forming mid-gap states responsible for recombination.

FIG. 19 depicts the effect of multiple healing cycles and repeated irradiation exposure on an exemplary OPV device. The following is the definition of the X axis: 1. Fresh; 2. Post-irradiation; 3. Thermal annealing; 4. Second irradiation; 5. Thermal annealing. The OPV device demonstrated the capacity to endure multiple healing cycles following repeated exposure to irradiation. The V_{OC} and J_{SC} maintained up to 95% of their performance after two healing cycles, while the FF experienced a reduction of 10% with each cycle. PCE drops 20% for each cycles.

FIG. 20 depicts Matrix-assisted laser desorption ionization-time of flight mass spectrometry (MALDI-TOF-MS) traces for BT- before and after irradiation. No formation of new chemical species exhibiting mass lower than that of BT-CIC was observed.

FIG. 21 depicts Matrix-assisted laser desorption ionization-time of flight mass spectrometry (MALDI-TOF-MS) traces for Y6 before and after irradiation. No formation of new chemical species exhibiting mass lower than that of Y6 was observed.

FIG. 22 depicts Nuclear magnetic resonance (NMR) spectroscopy of BT-CIC and Y6 before and after irradiation. The new peak at δ=1.25 ppm in the irradiated BT-CIC is characteristic of the saturated alkyl chain in the molecule. No new proton peaks or chemical shifts were observed at the lower magnetic field.

### DETAILED DESCRIPTION

The present disclosure provides OPVs with improved radiation hardness.

Various non-limiting examples of OPVs and compositions within various layers of an OPV are described in greater detail below.

### Definitions

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of optoelectronic devices are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, the terms “electrode” and “contact” may refer to a layer that provides a medium for delivering current to an external circuit or providing a bias current or voltage to the device. For example, an electrode, or contact, may provide the interface between the active regions of an organic photosensitive optoelectronic device and a wire, lead, trace or other means for transporting the charge carriers to or from the external circuit. Examples of electrodes include anodes and cathodes, which may be used in a photosensitive optoelectronic device.

As used herein, the term “transparent” may refer to a material that permits at least 50% of the incident electromagnetic radiation in relevant wavelengths to be transmitted through it. In a photosensitive optoelectronic device, it may be desirable to allow the maximum amount of ambient electromagnetic radiation from the device exterior to be admitted to the photoconductive active interior region. That is, the electromagnetic radiation must reach a photoconductive layer(s), where it can be converted to electricity by photoconductive absorption. This often dictates that at least one of the electrical contacts or electrodes should be minimally absorbing and minimally reflecting of the incident electromagnetic radiation. In some cases, such a contact should be transparent or at least semi-transparent. In one embodiment, the transparent material may form at least part of an electrical contact or electrode.

As used herein, the term “semi-transparent” may refer to a material that permits some, but less than 50% transmission of ambient electromagnetic radiation in relevant wavelengths. Where a transparent or semi-transparent electrode is used, the opposing electrode may be a reflective material so that light which has passed through the cell without being absorbed is reflected back through the cell.

As used and depicted herein, a “layer” refers to a member or component of a device, for example an optoelectronic device, being principally defined by a thickness, for example in relation to other neighboring layers, and extending outward in length and width. It should be understood that the term “layer” is not necessarily limited to single layers or sheets of materials. In addition, it should be understood that the surfaces of certain layers, including the interface(s) of such layers with other material(s) or layers(s), may be imperfect, wherein said surfaces represent an interpenetrating, entangled or convoluted network with other material(s) or layer(s). Similarly, it should also be understood that a layer may be discontinuous, such that the continuity of said layer along the length and width may be disturbed or otherwise interrupted by other layer(s) or material(s).

As used herein, a “photoactive region” refers to a region of a device that absorbs electromagnetic radiation to generate excitons. Similarly, a layer is “photoactive” if it absorbs electromagnetic radiation to generate excitons. The excitons may dissociate into an electron and a hole in order to generate an electrical current.

As used herein, the term “cathode buffer” is given its ordinary meaning in the art and generally refers to a material which is disposed between a cathode and a photoactive material. Generally, a cathode buffer material aids in reducing the work function of the cathode interface. Those of ordinary skill in the art will be able to select suitable cathode buffer materials with appropriate work functions for use in the methods and devices described herein.

As used herein, the term “anode buffer” is given its ordinary meaning in the art and generally refers to a material which is disposed between a anode and a photoactive material. Generally, a anode buffer material aids in reducing the work function of the anode interface. Those of ordinary skill in the art will be able to select suitable anode buffer materials with appropriate work functions for use in the methods and devices described herein.

As used herein, the terms “donor” and “acceptor” refer to the relative positions of the highest occupied molecular orbital (“HOMO”) and lowest unoccupied molecular orbital (“LUMO”) energy levels of two contacting but different organic materials. If the LUMO energy level of one material in contact with another is lower, then that material is an acceptor. Otherwise it is a donor. It is energetically favorable, in the absence of an external bias, for electrons at a donor-acceptor junction to move into the acceptor material, and for holes to move into the donor material.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

As used herein, the term “band gap” (E_{g}) of a polymer may refer to the energy difference between the HOMO and the LUMO. The band gap is typically reported in electron volts (eV). The band gap may be measured from the UV-vis spectroscopy or cyclic voltammetry. A “low band gap” polymer may refer to a polymer with a band gap below 2 eV, e.g., the polymer absorbs light with wavelengths longer than 620 nm.

As used herein, the term “excitation binding energy” (E_{B}) may refer to the following formula: E_{B}=(M⁺+M⁻)−(M*+M), where M⁺ and M⁻ are the total energy of a positively and negatively charged molecule, respectively; M* and M are the molecular energy at the fust singlet state (S₁) and ground state, respectively. Excitation binding energy of acceptor or donor molecules affects the energy offset needed for efficient exciton dissociation. In certain examples, the escape yield of a hole increases as the HOMO offset increases. A decrease of exciton binding energy E_{B} for the acceptor molecule leads to an increase of hole escape yield for the same HOMO offset between donor and acceptor molecules.

As used herein, “power conversion efficiency” (PCE) (η_{ρ}) may be expressed as:

$${η}_{ρ} = \frac{{V}_{OC} * FF * {J}_{SC}}{{P}_{O}}$$

wherein V_{OC} is the open circuit voltage, FF is the fill factor, J_{SC} is the short circuit current, and P_{O} is the input optical power.

As used herein, “spin coating” may refer to the process of solution depositing a layer or film of one material (i.e., the coating material) on a surface of an adjacent substrate or layer of material. The spin coating process may include applying a small amount of the coating material on the center of the substrate, which is either spinning at low speed or not spinning at all. The substrate is then rotated at high speed in order to spread the coating material by centrifugal force. Rotation is continued while the fluid spins off the edges of the substrate, until the desired thickness of the film is achieved. The applied solvent is usually volatile, and simultaneously evaporates. Therefore, the higher the angular speed of spinning, the thinner the film. The thickness of the film also depends on the viscosity and concentration of the solution and the solvent.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the fust energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

The terms “halo,” “halogen,” and “halide” are used interchangeably and refer to fluorine, chlorine, bromine, and iodine.

The term “pseudohalogen” refers to polyatomic analogues of halogens, whose chemistry, resembling that of the true halogens, allows them to substitute for halogens in several classes of chemical compounds. Exemplary pseudohalogens include, but are not limited to, nitrile, cyaphide, isocyanide, cyanate, isocyanate, fulminate, thiocyanate, isothiocyanate, selenocyanate, tellurocyanate, azide, tetracarbonylcobaltate, trinitromethanide, and tricyanomethanide groups.

The term “acyl” refers to a substituted carbonyl radical (C(O)—Rₛ).

The term “ester” refers to a substituted oxycarbonyl (—O—C(O)—Rₛ or —C(O)—O—Rₛ) radical.

The term “ether” refers to an —ORₛ radical.

The terms “sulfanyl” or “thio-ether” are used interchangeably and refer to a —SRₛ radical.

The term “sulfinyl” refers to a —S(O)—Rₛ radical.

The term “sulfonyl” refers to a —SO₂—Rₛ radical.

The term “phosphino” refers to a —P(Rₛ)₃ radical, wherein each Rₛ can be same or different.

The term “silyl” refers to a —Si(Rₛ)₃ radical, wherein each Rₛ can be same or different.

The term “boryl” refers to a —B(Rₛ)₂ radical or its Lewis adduct —B(Rs)3 radical, wherein Rs can be same or different.

In each of the above, Rₛ can be hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, and combination thereof. Preferred Rₛ is selected from the group consisting of alkyl, cycloalkyl, aryl, heteroaryl, and combination thereof.

The term “alkyl” refers to and includes both straight and branched chain alkyl radicals. Preferred alkyl groups are those containing from one to fifteen carbon atoms and includes methyl, ethyl, propyl, 1-methylethyl, butyl, 1-methylpropyl, 2-methylpropyl, pentyl, 1-methylbutyl, 2-methylbutyl, 3-methylbutyl, 1,1-dimethylpropyl, 1,2-dimethylpropyl, 2,2-dimethylpropyl, and the like. Additionally, the alkyl group is optionally substituted.

The term “cycloalkyl” refers to and includes monocyclic, polycyclic, and spiro alkyl radicals. Preferred cycloalkyl groups are those containing 3 to 12 ring carbon atoms and includes cyclopropyl, cyclopentyl, cyclohexyl, bicyclo[3.1.1]heptyl, spiro[4.5]decyl, spiro[5.5]undecyl, adamantyl, and the like. Additionally, the cycloalkyl group is optionally substituted.

The terms “heteroalkyl” or “heterocycloalkyl” refer to an alkyl or a cycloalkyl radical, respectively, having at least one carbon atom replaced by a heteroatom. Optionally the at least one heteroatom is selected from O, S, N, P, B, Si and Se, preferably, O, S or N. Additionally, the heteroalkyl or heterocycloalkyl group is optionally substituted.

The term “alkenyl” refers to and includes both straight and branched chain alkene radicals. Alkenyl groups are essentially alkyl groups that include at least one carbon-carbon double bond in the alkyl chain. Cycloalkenyl groups are essentially cycloalkyl groups that include at least one carbon-carbon double bond in the cycloalkyl ring. The term “heteroalkenyl” as used herein refers to an alkenyl radical having at least one carbon atom replaced by a heteroatom. Optionally the at least one heteroatom is selected from O, S, N, P, B, Si, and Se, preferably, O, S, or N. Preferred alkenyl, cycloalkenyl, or heteroalkenyl groups are those containing two to fifteen carbon atoms. Additionally, the alkenyl, cycloalkenyl, or heteroalkenyl group is optionally substituted.

The term “alkynyl” refers to and includes both straight and branched chain alkyne radicals. Preferred alkynyl groups are those containing two to fifteen carbon atoms. Additionally, the alkynyl group is optionally substituted.

The terms “aralkyl” or “arylalkyl” are used interchangeably and refer to an alkyl group that is substituted with an aryl group. Additionally, the aralkyl group is optionally substituted.

The term “heterocyclic group” refers to and includes aromatic and non-aromatic cyclic radicals containing at least one heteroatom. Optionally the at least one heteroatom is selected from O, S, N, P, B, Si, and Se, preferably, O, S, or N. Hetero-aromatic cyclic radicals may be used interchangeably with heteroaryl. Preferred hetero-non-aromatic cyclic groups are those containing 3 to 7 ring atoms which includes at least one hetero atom, and includes cyclic amines such as morpholino, piperidino, pyrrolidino, and the like, and cyclic ethers/thio-ethers, such as tetrahydrofuran, tetrahydropyran, tetrahydrothiophene, and the like. Additionally, the heterocyclic group may be optionally substituted.

The term “aryl” refers to and includes both single-ring aromatic hydrocarbyl groups and polycyclic aromatic ring systems. The polycyclic rings may have two or more rings in which two carbons are common to two adjoining rings (the rings are “fused”) wherein at least one of the rings is an aromatic hydrocarbyl group, e.g., the other rings can be cycloalkyls, cycloalkenyls, aryl, heterocycles, and/or heteroaryls. Preferred aryl groups are those containing six to thirty carbon atoms, preferably six to twenty carbon atoms, more preferably six to twelve carbon atoms. Especially preferred is an aryl group having six carbons, ten carbons or twelve carbons. Suitable aryl groups include phenyl, biphenyl, triphenyl, triphenylene, tetraphenylene, naphthalene, anthracene, phenalene, phenanthrene, fluorene, pyrene, chrysene, perylene, and azulene, preferably phenyl, biphenyl, triphenyl, triphenylene, fluorene, and naphthalene. Additionally, the aryl group is optionally substituted.

The term “heteroaryl” refers to and includes both single-ring aromatic groups and polycyclic aromatic ring systems that include at least one heteroatom. The heteroatoms include, but are not limited to O, S, N, P, B, Si, and Se. In many instances, O, S, or N are the preferred heteroatoms. Hetero-single ring aromatic systems are preferably single rings with 5 or 6 ring atoms, and the ring can have from one to six heteroatoms. The hetero-polycyclic ring systems can have two or more rings in which two atoms are common to two adjoining rings (the rings are “fused”) wherein at least one of the rings is a heteroaryl, e.g., the other rings can be cycloalkyls, cycloalkenyls, aryl, heterocycles, and/or heteroaryls. The hetero-polycyclic aromatic ring systems can have from one to six heteroatoms per ring of the polycyclic aromatic ring system. Preferred heteroaryl groups are those containing three to thirty carbon atoms, preferably three to twenty carbon atoms, more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group is optionally substituted.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, and benzimidazole, and the respective aza-analogs of each thereof are of particular interest.

The terms alkyl, cycloalkyl, heteroalkyl, heterocycloalkyl, alkenyl, cycloalkenyl, heteroalkenyl, alkynyl, aralkyl, heterocyclic group, aryl, and heteroaryl, as used herein, are independently unsubstituted, or independently substituted, with one or more general substituents.

In many instances, the general substituents are selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof.

In some instances, the preferred general substituents are selected from the group consisting of deuterium, fluorine, alkyl, cycloalkyl, heteroalkyl, alkoxy, aryloxy, amino, silyl, alkenyl, cycloalkenyl, heteroalkenyl, aryl, heteroaryl, nitrile, isonitrile, sulfanyl, and combinations thereof.

In some instances, the preferred general substituents are selected from the group consisting of deuterium, fluorine, alkyl, cycloalkyl, alkoxy, aryloxy, amino, silyl, aryl, heteroaryl, sulfanyl, and combinations thereof.

In yet other instances, the more preferred general substituents are selected from the group consisting of deuterium, fluorine, alkyl, cycloalkyl, aryl, heteroaryl, and combinations thereof.

The terms “substituted” and “substitution” refer to a substituent other than H that is bonded to the relevant position, e.g., a carbon or nitrogen. For example, when R¹ represents mono-substitution, then one R¹ must be other than H (i.e., a substitution). Similarly, when R¹ represents di-substitution, then two of R¹ must be other than H. Similarly, when R¹ represents no substitution, R¹, for example, can be a hydrogen for available valencies of ring atoms, as in carbon atoms for benzene and the nitrogen atom in pyrrole, or simply represents nothing for ring atoms with fully filled valencies, e.g., the nitrogen atom in pyridine. The maximum number of substitutions possible in a ring structure will depend on the total number of available valencies in the ring atoms.

As used herein, “combinations thereof” indicates that one or more members of the applicable list are combined to form a known or chemically stable arrangement that one of ordinary skill in the art can envision from the applicable list. For example, an alkyl and deuterium can be combined to form a partial or fully deuterated alkyl group; a halogen and alkyl can be combined to form a halogenated alkyl substituent; and a halogen, alkyl, and aryl can be combined to form a halogenated arylalkyl. In one instance, the term substitution includes a combination of two to four of the listed groups. In another instance, the term substitution includes a combination of two to three groups. In yet another instance, the term substitution includes a combination of two groups. Preferred combinations of substituent groups are those that contain up to fifty atoms that are not hydrogen or deuterium, or those which include up to forty atoms that are not hydrogen or deuterium, or those that include up to thirty atoms that are not hydrogen or deuterium. In many instances, a preferred combination of substituent groups will include up to twenty atoms that are not hydrogen or deuterium.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[f,h]quinoxaline and dibenzo[f,h]quinoline. One of ordinary skill in the art can readily envision other nitrogen analogs of the aza-derivatives described above, and all such analogs are intended to be encompassed by the terms as set forth herein.

As used herein, “deuterium” refers to an isotope of hydrogen. Deuterated compounds can be readily prepared using methods known in the art. For example, U.S. Pat. No. 8,557,400, Patent Pub. No. WO 2006/095951, and U.S. Pat. Application Pub. No. US 2011/0037057, which are hereby incorporated by reference in their entireties, describe the making of deuterium-substituted organometallic complexes. Further reference is made to Ming Yan, et al., Tetrahedron 2015, 71, 1425-30 and Atzrodt et al., Angew. Chem. Int. Ed. (Reviews) 2007, 46, 7744-65, which are incorporated by reference in their entireties, describe the deuteration of the methylene hydrogens in benzyl amines and efficient pathways to replace aromatic ring hydrogens with deuterium, respectively.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In some instance, a pair of adjacent substituents can be optionally joined or fused into a ring. The preferred ring is a five, six, or seven-membered carbocyclic or heterocyclic ring, includes both instances where the portion of the ring formed by the pair of substituents is saturated and where the portion of the ring formed by the pair of substituents is unsaturated. As used herein, “adjacent” means that the two substituents involved can be on the same ring next to each other, or on two neighboring rings having the two closest available substitutable positions, such as 2, 2′ positions in a biphenyl, or 1, 8 position in a naphthalene, as long as they can form a stable fused ring system.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and organic vapor jet printing (OVJP). Other methods nay also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processability than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention can be incorporated into a wide variety of electronic component modules (or units) that can be incorporated into a variety of electronic products or intermediate components.

The materials and structures described herein may have applications in devices other than organic solar cells. For example, other optoelectronic devices such as organic electroluminescent devices (OLEDs) and organic photodetectors may employ the materials and structures. More generally, organic devices, such as organic transistors, may employ the materials and structures.

According to one aspect, the present disclosure relates to a compound of Formula I, Formula II, Formula III, or Formula IV

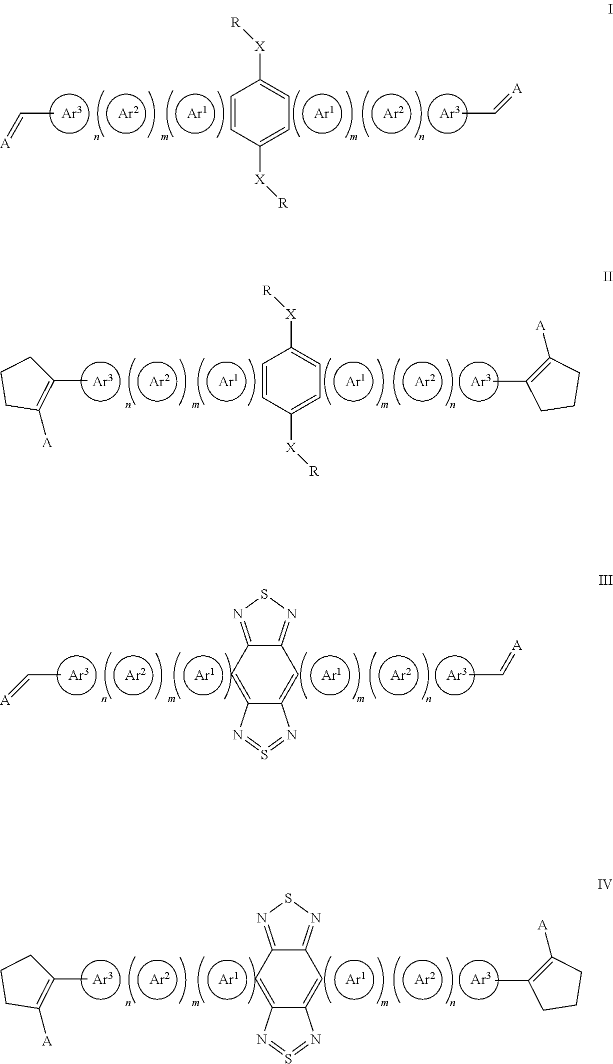

wherein:
Ar¹ is an aromatic group, which is conjugated, fused, or connected to a benzene ring, is selected from the group consisting of:

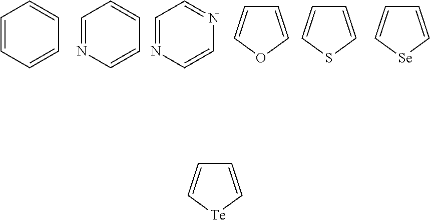

Ar² is an aromatic group, which is conjugated, fused, or connected to an Ar¹ ring, and is selected from the group consisting of:

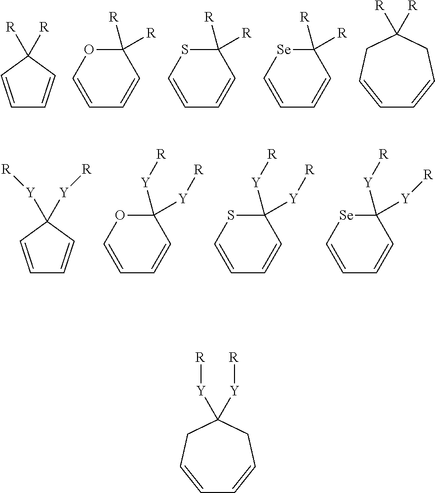

Ar³ is an aromatic group, which is conjugated, fused, or connected to an Ar² ring, is selected from the group consisting of:

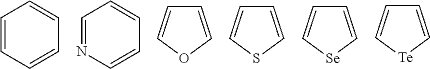

each X is independently selected from the group consisting of oxygen, sulfur, selenium, and nitrogen;
each R is independently an aromatic group;
m is from 0 to 10; and
n is from 0 to 10;
A is one of the following structures:

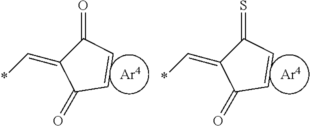 [SMILES: *C=C1C(=O)C=CC1=O ; */C=C1\C(=O)C=CC1=S]

Ar⁴ is an aromatic group, which is conjugated fused connected to an adjacent ring, is selected from the group consisting of:

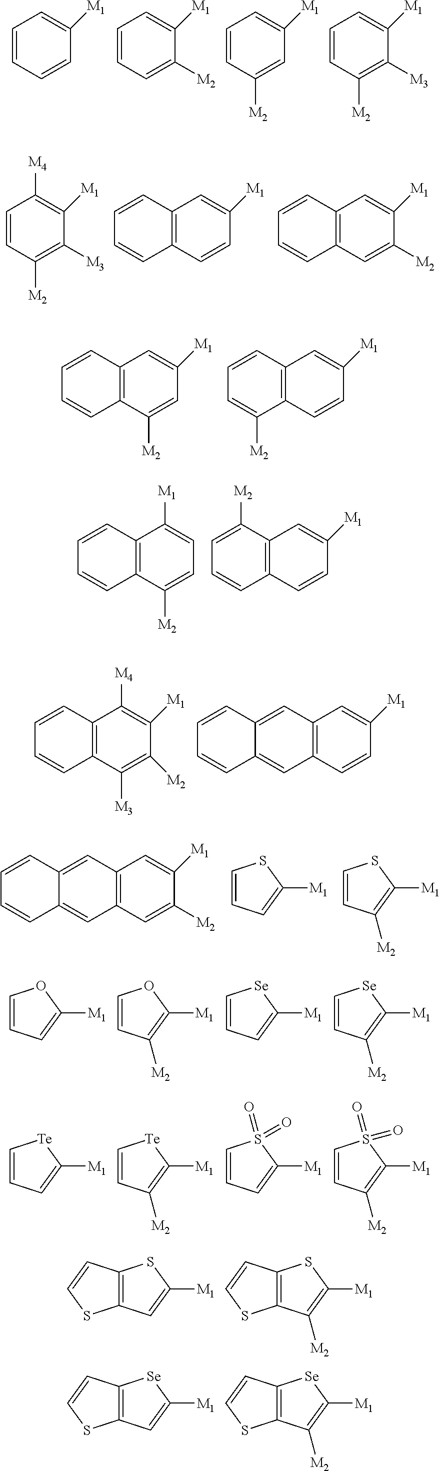

each M₁, M₂, M₃, and M₄ is independently selected from the group consisting of hydrogen, fluorine, chlorine, bromine, iodine, and cyano group, wherein at least one of M₁, M₂, M₃, and M₄ is a halogen.

In one embodiment, R is selected from the group consisting of:

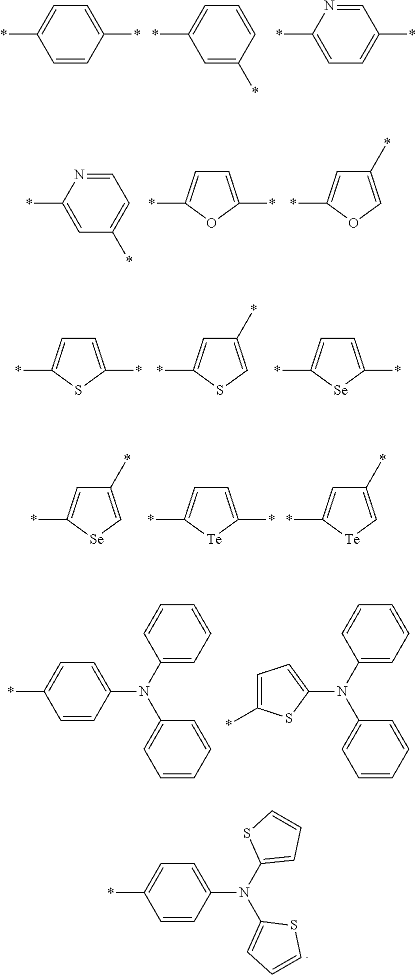

In one embodiment, the compound is represented by Formula I. In one embodiment, the compound is represented by Formula II. In one embodiment, the compound is represented by Formula III. In one embodiment, the compound is represented by Formula IV.

In one embodiment, n and m are each 1.

In one embodiment, A is

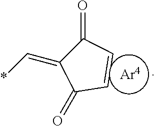 [SMILES: *C=C1C(=O)C=CC1=O]

In one embodiment, Ar⁴ is one of the following structures:

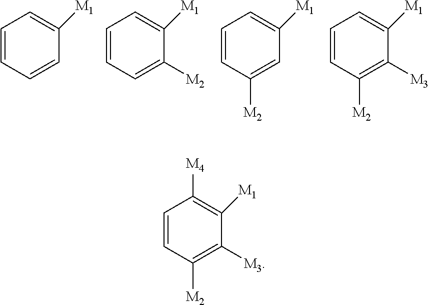

In one embodiment, each of M₁, M₂, M₃, and M₄ represents Cl. In one embodiment, the compound is nonsymmetric. In one embodiment, the compound has no alkyl chains.

According to another aspect, a formulation comprising a compound described herein is also disclosed.

### Organic Photovoltaic Cells

In one aspect, the invention relates to an OPV device comprising a compound of the disclosure. In one embodiment, the OPV device includes an anode; a cathode; and an active material positioned between the anode and cathode, wherein the active material comprises an acceptor and a donor.

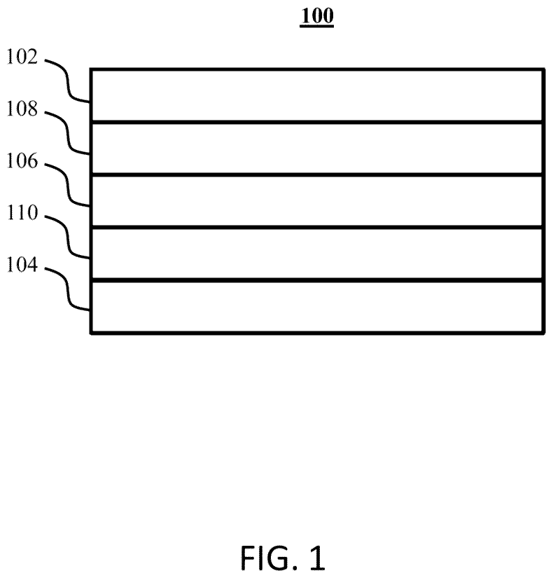

FIG. 1 depicts an example of various layers of a single-junction solar cell or organic photovoltaic cell (OPV) 100. The OPV cell may include two electrodes having an anode 102 and a cathode 104 in superposed relation, at least one donor composition, and at least one acceptor composition, wherein the donor-acceptor material or active layer 106 is positioned between the two electrodes 102, 104. In some embodiments, at least one intermediate layer 108 may be positioned between the anode 102 and the active layer 106. Additionally, or alternatively, at least one intermediate layer 110 may be positioned between the active layer 106 and cathode 104.

The anode 102 may include a conducting oxide, thin metal layer, or conducting polymer. In some examples, the anode 102 includes a (e.g., transparent) conductive metal oxide such as indium tin oxide (ITO), tin oxide (TO), gallium indium tin oxide (GITO), zinc oxide (ZO), or zinc indium tin oxide (ZITO). In other examples, the anode 102 includes a thin metal layer, wherein the metal is selected from the group consisting of Ag, Au, Pd, Pt, Ti, V, Zn, Sn, Al, Co, Ni, Cu, Cr, or combinations thereof. In yet other examples, the anode 102 includes a (e.g., transparent) conductive polymer such as polyanaline (PANI), or 3,4-polyethyl-enedioxythiophene:polystyrenesulfonate (PEDOT:PSS).

The thickness of the anode 102 may be 0.1-100 nm, 1-10 nm, 0.1-10 nm, or 10-100 nm.

The cathode 104 may be a conducting oxide, thin metal layer, or conducting polymer similar or different from the materials discussed above for the anode 102. In certain examples, the cathode 104 may include a metal or metal alloy. The cathode 104 may include Ca, Al, Mg, Ti, W, Ag, Au, or another appropriate metal, or an alloy thereof.

The thickness of the cathode 104 may be 0.1-100 nm, 1-10 nm, 0.1-10 nm, or 10-100 nm.

As noted above, the OPV may include one or more intermediate layers, for example charge collecting/transporting intermediate layers positioned between an electrode 102, 104 and the active region or layer 106. The intermediate layer 108, 110 may be a metal oxide. In certain examples, the intermediate layer 108, 110 includes MoO₃, V₂O₅, ZnO, or TiO₂. In some examples, the first intermediate layer 108 has a similar composition as the second intermediate layer 110. In other examples, the first and second intermediate layers 108, 110 have different compositions.

The thickness of each intermediate layer may be 0.1-100 nm, 1-10 nm, 0.1-10 nm, or 10-100 nm.

The active region or layer 106 positioned between the electrodes 102, 104 includes a composition or molecule having an acceptor and a donor. In some embodiments, the composition may be arranged as an acceptor-donor-acceptor (A-D-A).

In one embodiment, the OPV device comprises various layers of a tandem or multi-junction photovoltaic device. In one embodiment, the OPV device comprises two electrodes having an anode and a cathode in superposed relation, at least one donor composition, and at least one acceptor composition positioned within a plurality of active layers or regions between the two electrodes. Additional active layers or regions are also possible. In one embodiment, the anode and the cathode each independently comprise a conducting oxide, thin metal layer, or conducting polymer. Exemplary conducting oxides, metal layers, and conducting polymers are described elsewhere herein.

In one embodiment, the OPV device comprises one or more intermediate layers positioned between the anode and a first active layer. Additionally, or alternatively, at least one intermediate layer may be positioned between the second active layer and cathode. In one embodiment, the OPV device comprises one or more intermediate layers positioned between the first active layer and the second active layer. In one embodiment, the OPV device comprises a first intermediate layer. In one embodiment, the OPV device comprises a second intermediate layer. In one embodiment, the OPV device comprises a third intermediate layer. In one embodiment, the OPV device comprises both first and second intermediate layers. In one embodiment, the OPV device comprises both first and third intermediate layers. In one embodiment, the OPV device comprises both second and third intermediate layers. In one embodiment, the OPV device comprises first, second, and third intermediate layers. In one embodiment, the first, second, and/or third intermediate layer comprises a metal oxide. Exemplary metal oxides are described elsewhere herein.

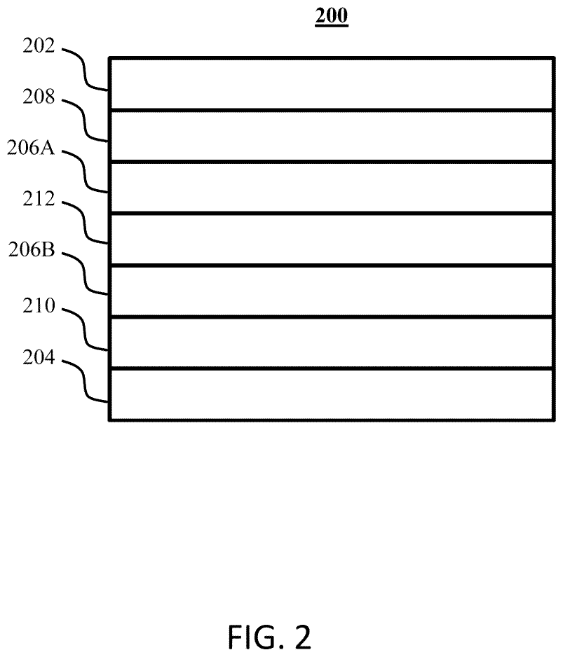

FIG. 2 depicts an example of various layers of a tandem or multi-junction solar cell or organic photovoltaic cell (OPV) 200. The OPV cell may include two electrodes having an anode 202 and a cathode 204 in superposed relation, at least one donor composition, and at least one acceptor composition positioned within a plurality of active layers or regions 206A, 206B between the two electrodes 202, 204. While only two active layers or regions 206A, 206B are depicted in FIG. 2, additional active layers or regions are also possible.

At least one intermediate layer 208 may be positioned between the anode 202 and a first active layer 206A. Additionally, or alternatively, at least one intermediate layer 210 may be positioned between the second active layer 206B and cathode 204.

At least one intermediate layer 212 may be positioned between the first active layer 206A and the second active layer 206B.

The compositions, thicknesses, etc. of each layer may be the same as those discussed with reference to FIG. 1.

The active region or layer 106, 206A, 206B positioned between the electrodes includes a composition or molecule having an acceptor and a donor. The composition may be arranged as an acceptor-donor-acceptor (A-D-A).

In one embodiment, the anode comprises a conducting oxide, thin metal layer, or conducting polymer. In one embodiment, the anode comprises a conductive metal oxide. Exemplary conductive metal oxides include, but are not limited to, indium tin oxide (ITO), tin oxide (TO), gallium indium tin oxide (GITO), zinc oxide (ZO), and zinc indium tin oxide (ZITO). In one embodiment, the anode comprises a metal layer. Exemplary metals for the metal layer include, but are not limited to, Ag, Au, Pd, Pt, Ti, V, Zn, Sn, Al, Co, Ni, Cu, Cr, and combinations thereof. In one embodiment, the metal layer comprises a thin metal layer. In one embodiment, the anode 102 comprises a conductive polymer. Exemplary conductive polymers include, but are not limited to, polyanaline (PANI), or 3,4-polyethyl-enedioxythiophene:polystyrenesulfonate (PEDOT:PSS). In one embodiment, thickness of the anode is between about 0.1-100 nm. In one embodiment, thickness of the anode is between about 1-10 nm. In one embodiment, thickness of the anode is between about 0.1-10 nm. In one embodiment, thickness of the anode is between about 10-100 nm. In one embodiment, anode comprises a transparent or semi-transparent conductive material.

In one embodiment, the cathode comprises a conducting oxide, a metal layer, or conducting polymer. Exemplary conducting oxide, metal layers, and conducting polymers are described elsewhere herein. In one embodiment, the cathode comprises a thin metal layer. In one embodiment, the cathode comprises a metal or metal alloy. In one embodiment, the cathode may comprise Ca, Al, Mg, Ti, W, Ag, Au, or another appropriate metal, or an alloy thereof. In one embodiment, the thickness of the cathode is between about 0.1-100 nm. In one embodiment, the thickness of the cathode is between about 1-10 nm. In one embodiment, the thickness of the cathode is between about 0.1-10 nm. In one embodiment, the thickness of the cathode is between about 10-100 nm. In one embodiment, cathode comprises a transparent or semi-transparent conductive material.

In one embodiment, the OPV device may comprise one or more charge collecting/transporting intermediate layers positioned between an electrode and the active region or layer. In one embodiment, the OPV device comprises one or more intermediate layers. In one embodiment, the intermediate layer comprises a metal oxide. Exemplary metal oxides include, but are not limited to, MoO₃, MoOₓ, V₂O₅, ZnO, and TiO₂. In one embodiment, the first intermediate layer has the same composition as the second intermediate layer. In one embodiment, the first intermediate layer and the second intermediate layer have different compositions. In one embodiment, the thickness of the intermediate layers are each independently between about 0.1-100 nm. In one embodiment, the thickness of the intermediate layers are each independently between about 1-10 nm. In one embodiment, the thickness of the intermediate layers are each independently between about 0.1-10 nm. In one embodiment, the thickness of the intermediate layers are each independently between about 10-100 nm.

### Consumer Products

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OPV that includes the compound of the present disclosure in the organic layer in the OPV is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

According to an embodiment, the devices fabricated in accordance with embodiments of the invention may be incorporated into one or more device selected from a consumer product, an electronic component module, a lighting panel, and/or a sign or display. Further examples of such electronic products or intermediate components include solar cells, light weight solar cells, flexible solar cells, solar cells integrated with thin film electronics including for power conversion and management, thin film power supply consisting of an OPV cell integrated with thin film electronics for power consumption and management, a solar farm including one or more OPV cells and/or devices that may be integrated in an array, solar farm including semi-transparent OPV cells and/or devices for advantages related to plants/crops, an OPV, device on a same substrate as a display, such as a thin film display, with integrated or external electronics, an OPV integrated with one or more sensors, including but not limited to mechanical, electrical and/or biological sensors, an OPV on a same substrate as a radio receive/transmitter, an OPV on a same substrate as an audio producing device, an OPV on the same substrate as a computing device, an OPV for powering IT devices, an OPV for powering shelf labels, an OPV for indoor applications, an OPV for integration with a window, wall, roof, etc., an OPV for use in a solar. In an embodiment, the OPV device may be fully or partially transparent, flexible, curved, rollable, foldable, or stretchable.

According to embodiments, the devices fabricated in accordance with embodiments of the invention may be incorporated with a battery on a same substrate as the device or connected to a battery on a different substrate/device. According to embodiments, the battery may be a standard battery and/or thin film battery.

According to embodiments, the devices fabricated may be a thin film OPV device. In an embodiment, a thin film device is one where the layers of the device are deposited as opposed to being placed on the substrate.

Combination with Other Materials

The materials described herein as useful for a particular layer in an organic optoelectronic device may be used in combination with a wide variety of other materials present in the device. The materials described or referred to below are non-limiting examples of materials that may be useful in combination with the compounds disclosed herein, and one of skill in the art can readily consult the literature to identify other materials that may be useful in combination.

### Conductivity Dopant

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### EXPERIMENTAL EXAMPLES

Similar to other emergent photovoltaic technologies, OPV have seen significant advancements over the past five years. For the efficiency, historically, the efficiency of OPVs has largely been driven by the choice of materials with different absorption band. As seen in this NREL chat, In the early 2010s, efficiencies using visible absorption materials P3HT and PCBM were ˜3%. This was followed by the introduction of donor-acceptor conjugated polymers, by enhancing the intramolecular charge transfer, these type of molecules can absorb the photons around 800 nm. The non-fullerene acceptors (NFAs) have now opened a new avenue for improved optical coverage, pushing the efficiency to ˜20% for single junction cell and ˜25% for tandem solar cells. On the other hand, by employing the blade-coating technique, The OPV modules with active areas larger than 200 cm\hat{ }2 reach efficiencies of up to 14.5%. This achievement demonstrates the scalability potential of OPV technology. Regarding reliability, an increasing number of studies are showcasing good photostability in OPVs. Notably, during indoor testing, accelerated aging methods have been employed to evaluate their durability, revealing an extrapolated intrinsic lifetime of over 30 years. Moreover, OPV modules have exhibited impressive stability in outdoor conditions, with a degradation rate below 2% per year following an initial period of rapid burn-in loss. All of this progress suggests that the OPV technology has the potential to serve as a viable energy provider in the future.

However, one opportunity that has often been overlooked for OPV technology is its application in space, particularly when considering its exceptionally high specific power value. Due to the substantial improvements in efficiency and the development of ultra-lightweight devices, the specific power for OPV can rise up to 40 W/g, which is approximately ten times greater than that of silicon panels. Furthermore, the inherent nature of low-temperature processing of OPVs suggests a potential capability for in-space manufacturing, taking advantage of the vacuum conditions in space environments. Which is essential for the deep space missions.

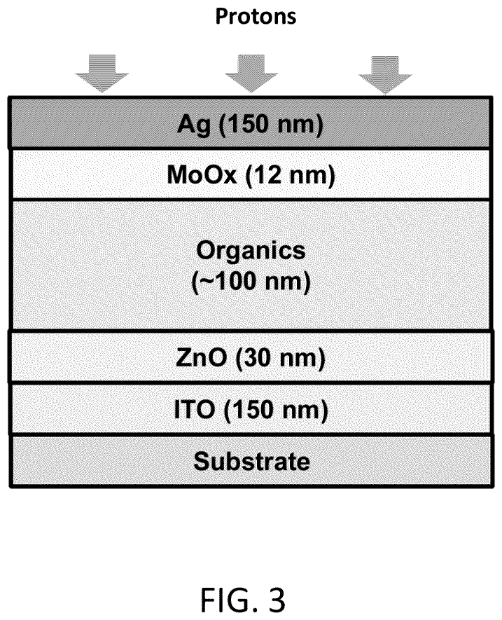

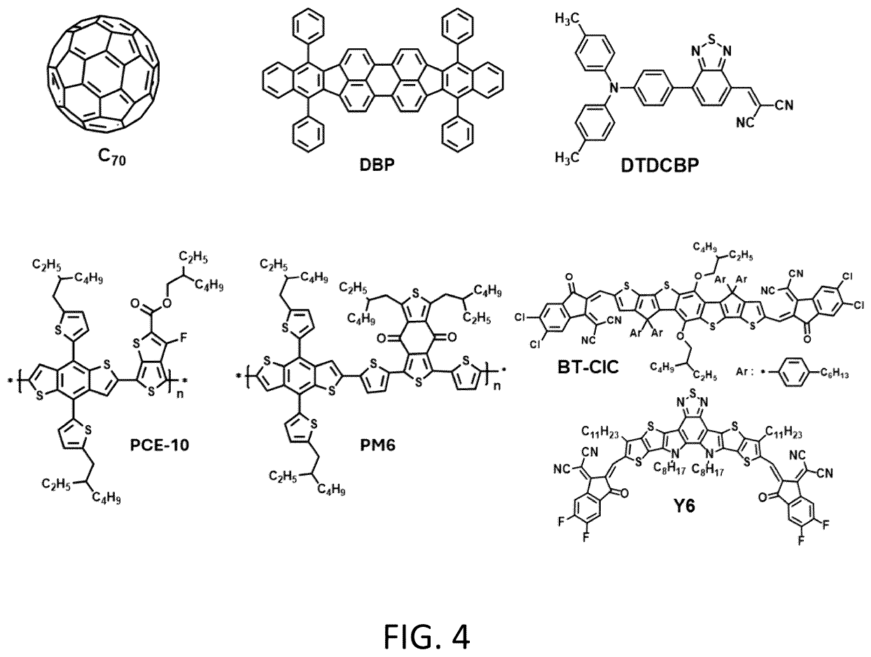

The archetype single-junction OPVs studied are shown in FIG. 3: one comprising a mixed donor and acceptor active region (DBP (see Burlingame, et al., Nature, 2019) and DTDCPB (see Li, et al., J. Am. Chem. Soc., 2019), as donors, and C₇₀ as the acceptor, respectively) grown by VTE, and the second consisting of a solution-processed polymer donor (PCE-10 (Li, et al., J. Am. Chem. Soc., 2017) and PM6 (Qian, et al., Macromolecules, 2012)) and a small molecule acceptor (BT-CIC (Li, et al., J. Am. Chem. Soc., 2017) and Y6 (Yuan, et al., Joule, 2019), see Methods for the nomenclatures of the materials used, with their molecular structural formulas provided in FIG. 4). A feature differentiating these two molecular families is that the VTE-grown (at top) small molecules lack bulky alkyl side chains compared to the solution-processed materials at bottom.

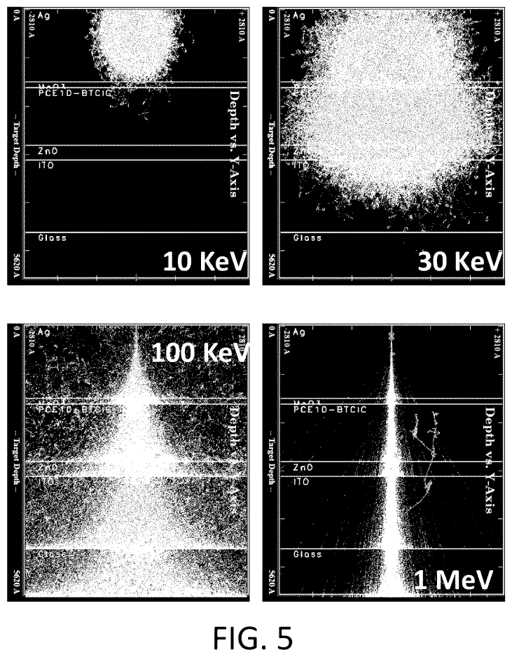

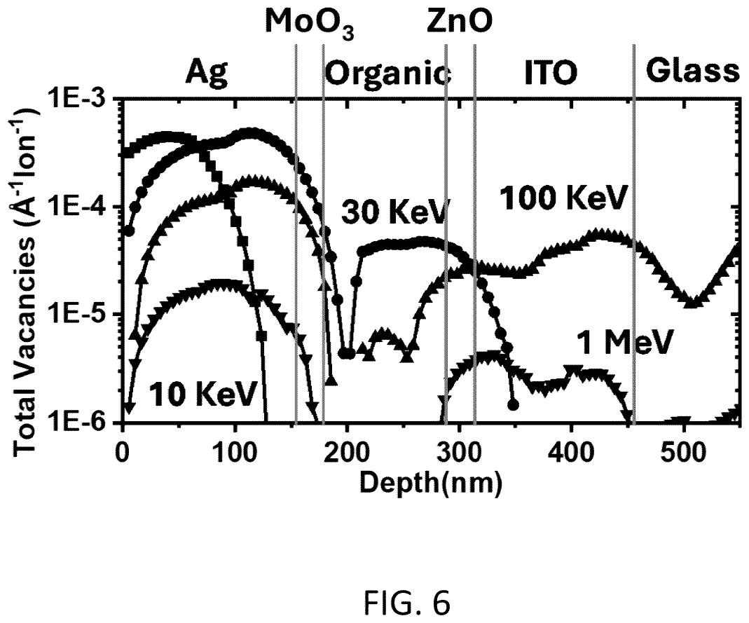

Studies of proton interactions with c-Si and GaAs solar cells have led to established guidelines for their ground-based testing (see Summers, et al., Radiat. Meas., 1995; Messenger, et al., IEEE Trans. Nucl. Sci., 2006; and Durant, et al., ACS Energy Lett., 2021), whereas no such standardized stability tests for OPVs are available. Compared to thicker inorganic solar cells, OPVs have an active region typically less than a hundred nanometers. High energy particles can penetrate the bulk heterojunction (BHJ) comprising blends of molecules composed of low molecular weight atoms, leading to minor displacement damage. Consequently, low-energy protons are preferable for testing the radiation hardness of OPVs. Additionally, if the irradiation is conducted from the illuminated side of the OPVs, even a thin PET substrate (125 μm) can effectively block<1 MeV protons. Therefore, the simulated ballistic ranges of protons with energies of 10, 30, 100 keV and 1 MeV incident on the Ag cathode of OPVs with 100 nm-thick absorber layers using matter/transport of ions in matter (SRIM/TRIM) protocols (see Ziegler, et al., Nucl. Instruments Methods Phys. Res. Sect. B Beam Interact. with Mater. Atoms, 2010) (see FIG. 5). The 30 keV protons have the highest probability of stopping in the thin BHJ, (see Messenger, et al., IEEE Trans. Nucl. Sci., 2006; Messenger, et al., Prog. Photovoltaics Res. Appl., 2001), whereas 10 keV protons are unable to penetrate the Ag electrode. Protons with energies≥100 keV have a stopping range>1 mm, which exceeds the OPV active region thickness. The calculations also provide the vacancies generated per proton created within the BHJ layer at each proton energy (see FIG. 6). Consequently, 30 keV protons create the highest number of vacancies in the BHJ and will be the focus of the following discussion. The 30 keV protons are most effective in creating a uniform damage profile throughout the thin BHJ due to their extensive interaction with the organic materials, These results are consistent with the total vacancies per proton created within the BHJ layer for each proton energy scenario (FIG. 6). The 30 keV protons create the highest number of vacancies in the organic BHJ. Further study focused on a proton energy of 30 keV to study its impact on OPV performance.

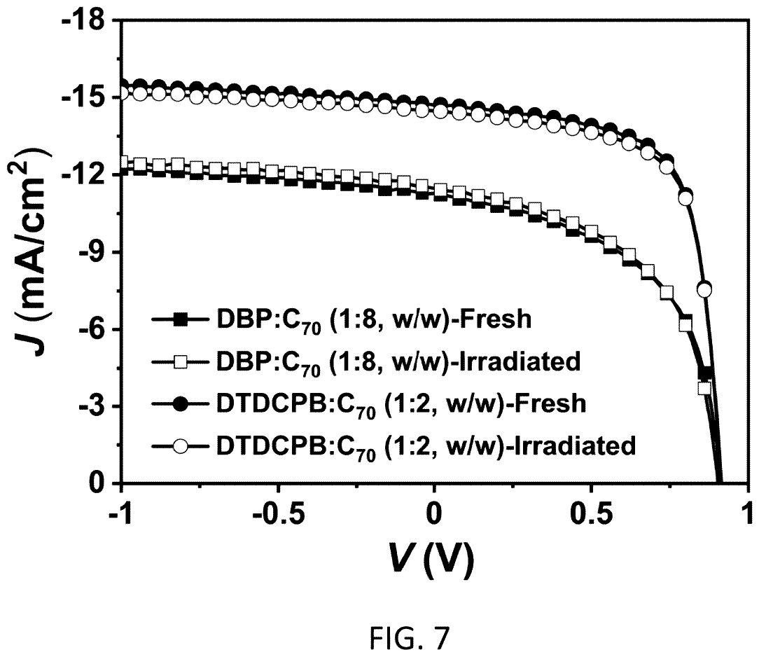

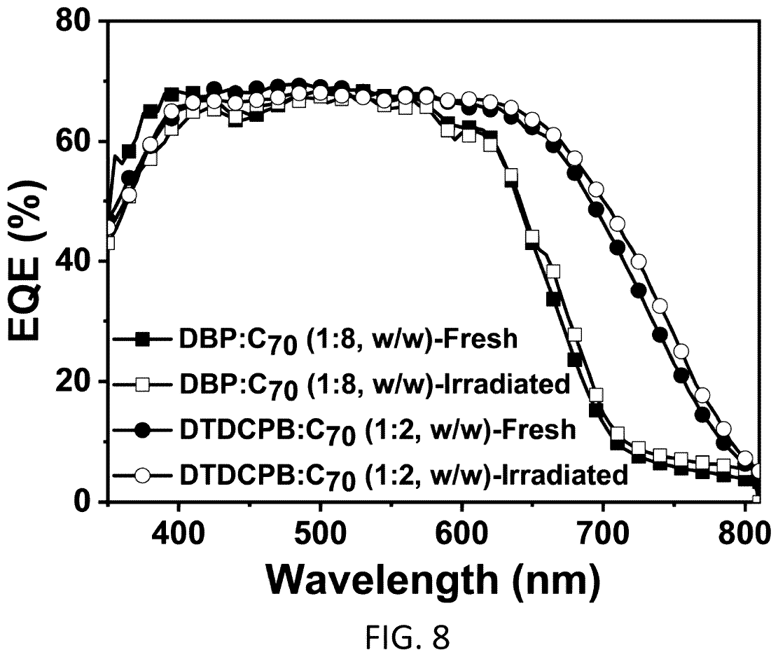

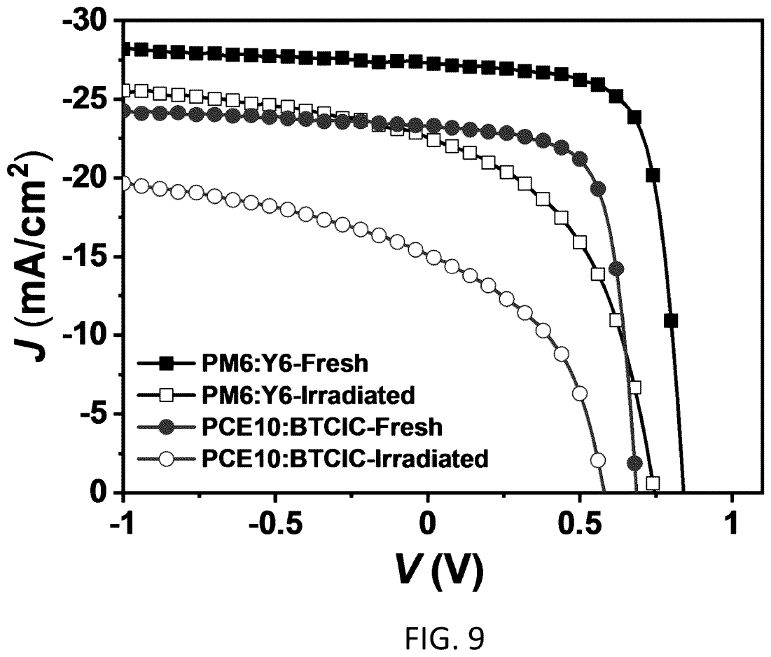

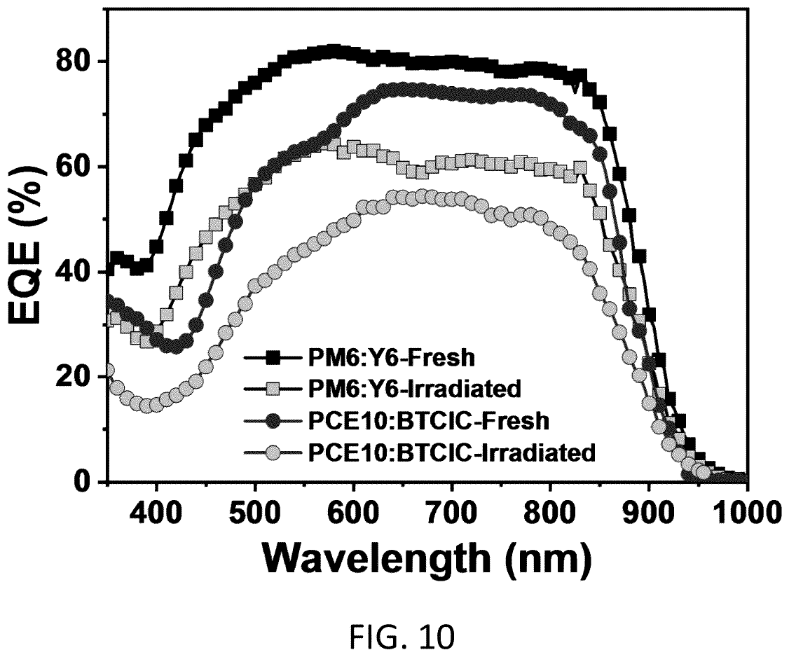

The external quantum efficiency (EQE) spectrum and current density-voltage (J-V) characteristics under 1 sun, AM1.5G solar spectral illumination of the devices before and after 30 keV proton irradiation at a fluence of 10¹² cm⁻² are plotted in FIG. 7 through FIG. 10, with a summary of their performance in Table 1. Here, PCE=16.2±0.3% for the as-grown PM6:Y6-based device, and 11.0±0.3% for the PCE-10:BT-CIC-based device. In contrast, the VTE-grown OPVs exhibited PCE=9.4±0.2% for DTDCPB:C₇₀ and 5.4±0.2% for DBP:C₇₀, respectively. Note that fullerene-based small molecule OPVs show a lower PCE compared to the polymer cells due to the reduced near infrared (NIR) absorption of the former devices.

TABLE 1

| Material | Fluences | | Jsc | | | | PCE_{after}/PCE_{before} |
|---|---|---|---|---|---|---|---|
| (Type) | (cm⁻²) | | (mA/cm²) | Voc (V) | FF | PCE (%) | (%) |
| DBP:C₇₀ | 10¹² | Before | 11.20 ± 0.33 | 0.90 ± | 0.54 ± | 5.44 ± 0.19 | 105 |
| (Small | | | | 0.01 | 0.01 | | |
| molecule) | | After | 11.63 ± 0.21 | 0.90 ± | 0.55 ± | 5.71 ± 0.12 | |
| | | | | 0.01 | 0.01 | | |
| DTDCPB:C₇₀ | 10¹² | Before | 14.85 ± 0.49 | 0.91 ± | 0.69 ± | 9.35 ± 0.23 | 99 |
| (Small | | | | 0.01 | 0.01 | | |
| molecule) | | After | 14.44 ± 0.39 | 0.91 ± | 0.70 ± | 9.24 ± 0.19 | |
| | | | | 0.01 | 0.01 | | |
| PCE-10:BT-CIC | 10¹² | Before | 23.03 ± 0.45 | 0.69 ± | 0.69 ± | 10.98 ± 0.32 | 36 |
| (Polymer) | | | | 0.01 | 0.01 | | |
| | | After | 15.31 ± 0.20 | 0.58 ± | 0.44 ± | 3.93 ± 0.16 | |
| | | | | 0.01 | 0.01 | | |
| PM6:Y6 | 10¹² | Before | 27.11 ± 0.56 | 0.84 ± | 0.71 ± | 16.22 ± 0.33 | 50 |
| (Polymer) | | | | 0.01 | 0.01 | | |
| | | After | 22.55 ± 0.25 | 0.74 ± | 0.48 ± | 7.98 ± 0.21 | |
| | | | | 0.01 | 0.01 | | |

After irradiation, both the PCE-10:BT-CIC, and PM6:Y6 cells show rapid degradation of their J-V and EQE characteristics (see Table 1). In contrast, the VTE-deposited small molecule OPV performance remains largely unchanged before and after irradiation.

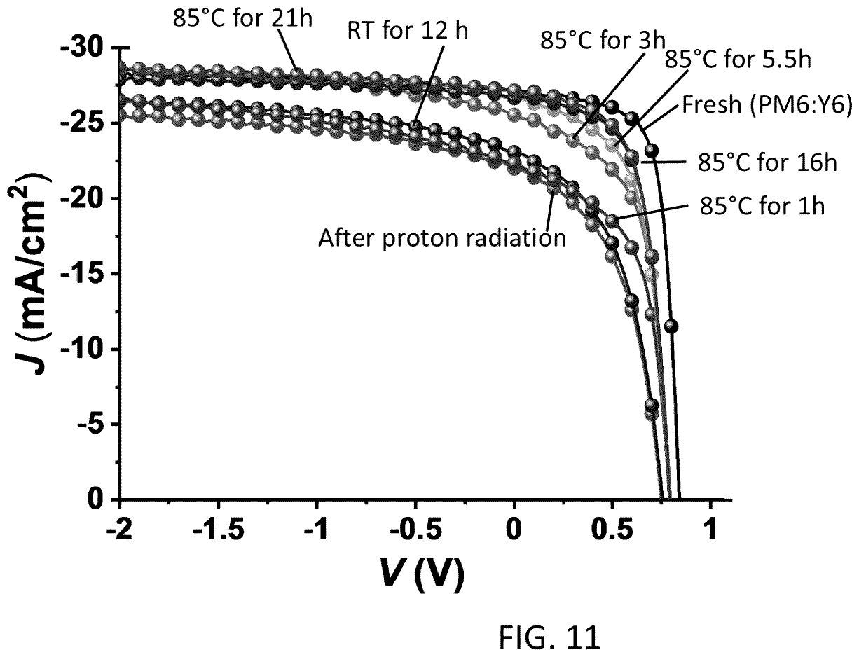

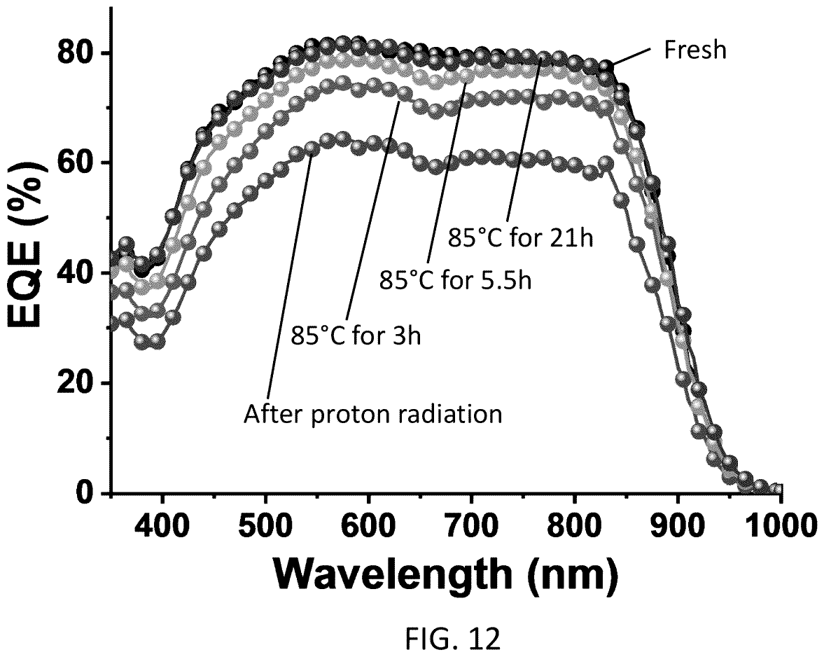

A recovery in device characteristics was observed in proton-irradiated PM6:Y6 OPVs after heating to 85±1° C. for 21 h, as plotted in FIG. 11 and FIG. 12, with details in Table 2. After annealing, the performance of the irradiated device is largely restored, with the PCE reaching nearly 90% of its value before irradiation. While the short circuit current density (J_{SC}) fully recovers, there was a 5% reduction in open-circuit voltage (V_{OC}) and a 10% reduction in fill factor (FF).

TABLE 2

| Active layer | V_{OC} (V) | J_{SC} (mA/cm²) | FF | PCE (%) | PCEₜ/PCE₀ (%) |
|---|---|---|---|---|---|
| PM:Y6 (Fresh) | 0.84 ± 0.01 | 27.11 ± 0.43 | 0.71 ± 0.02 | 16.22 ± 0.47 | — |
| After Proton Irradiation | 0.74 ± 0.01 | 22.55 ± 0.22 | 0.48 ± 0.02 | 7.98 ± 0.18 | 50 |
| Room Temperature 12 h | 0.76 ± 0.01 | 23.04 ± 0.53 | 0.49 ± 0.01 | 8.56 ± 0.36 | 53 |
| 85° C. for 1 h | 0.80 ± 0.01 | 22.34 ± 0.37 | 0.56 ± 0.02 | 10.04 ± 0.30 | 62 |
| 85° C. for 3 h | 0.80 ± 0.01 | 25.39 ± 0.23 | 0.59 ± 0.01 | 12.07 ± 0.42 | 75 |
| 85° C. for 5.5 h | 0.80 ± 0.01 | 26.64 ± 0.18 | 0.60 ± 0.02 | 12.74 ± 0.19 | 79 |
| 85° C. for 16 h | 0.80 ± 0.01 | 26.96 ± 0.29 | 0.62 ± 0.01 | 13.15 ± 0.16 | 81 |
| 85° C. for 21 h | 0.80 ± 0.01 | 27.12 ± 0.36 | 0.63 ± 0.01 | 13.61 ± 0.21 | 84 |
| 85° C. for 93 h | 0.80 ± 0.01 | 27.43 ± 0.33 | 0.63 ± 0.01 | 13.81 ± 0.26 | 85 |

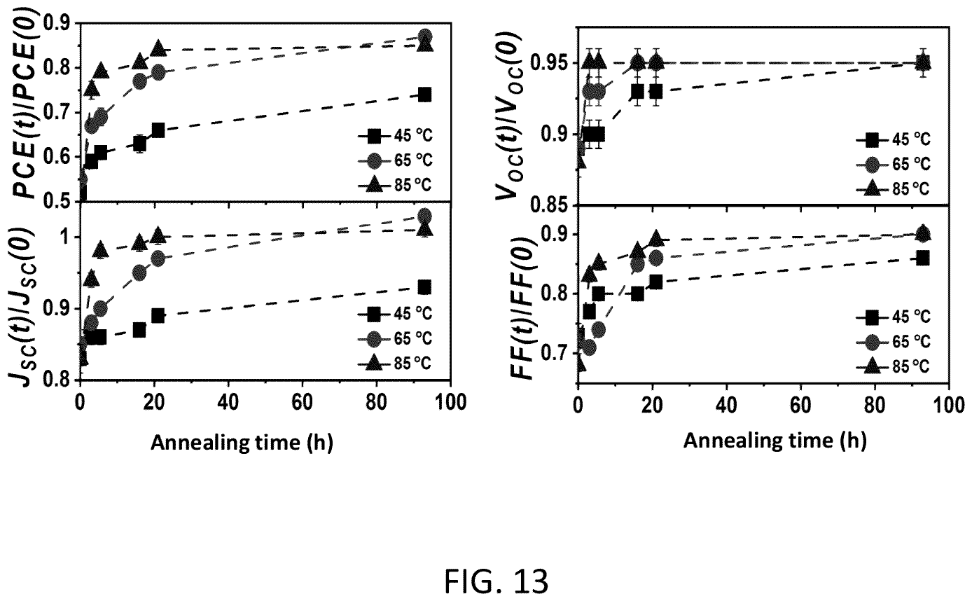

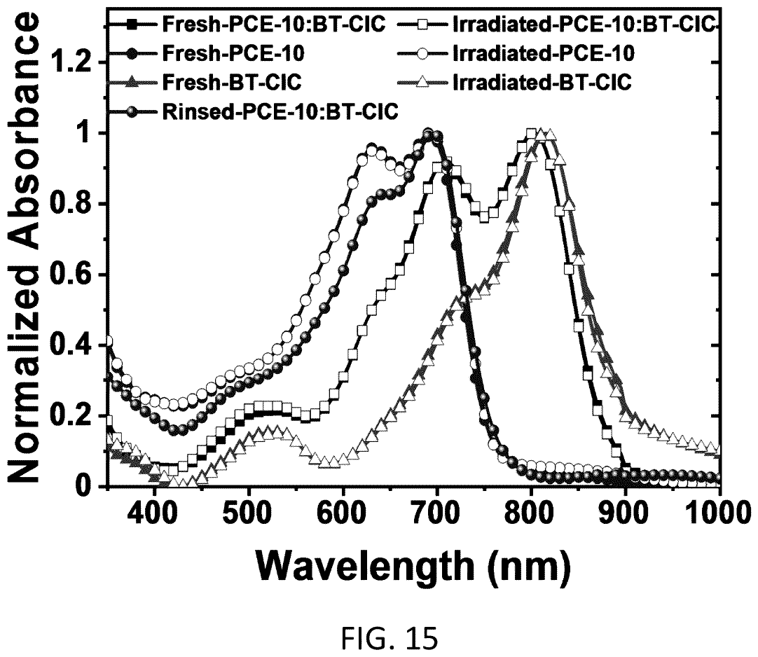

FIG. 13 shows Jse, V_{OC}, FF, and PCE as functions of annealing time at temperatures of 45±1° C., 65±1° C., and 85±1° C. in a N₂ filled glove box. Compared to the temperatures of 65±1° C. and 85±1° C., where the PCE recovers by approximately 90% of the non-irradiated value after 93 h, at 45±1° C. only 70% of the efficiency was restored. Moreover, the thermally annealed PM6:Y6 devices were exposed to a second round of proton radiation with the same 30 keV fluence, followed by thermal annealing at same conditions as before. The performance outcomes of this experiment are detailed in FIG. 15. The V_{OC} and J_{SC} for the doubly irradiated PM6:Y6 device also rebounded to approximately 95% of the initial efficiency, and the FF again exhibited a 10% decrease, therefore resulting in a 20% loss in PCE for each cycle. In particularly, The J_{SC} was fully restored. Notably, all proton-irradiated devices exhibited pronounced performance enhancements following an annealing period of 93 hours. Remarkably, at annealing temperatures of 65° C. and 85° C., devices displayed significant recovery with the PCE remaining factor reaching approximately 90% of the initial value, J_{SC} was restored fully, while V_{OC} and FF experienced only a 5% and 10% decline, respectively. On the contrary, after 93 hours of annealing at 45° C., there was a considerable reduction in the PCE remaining factor, only about 70% of the initial efficiency was achieved. These observations clearly demonstrate that the healing of radiation-induced defects is thermally activated.

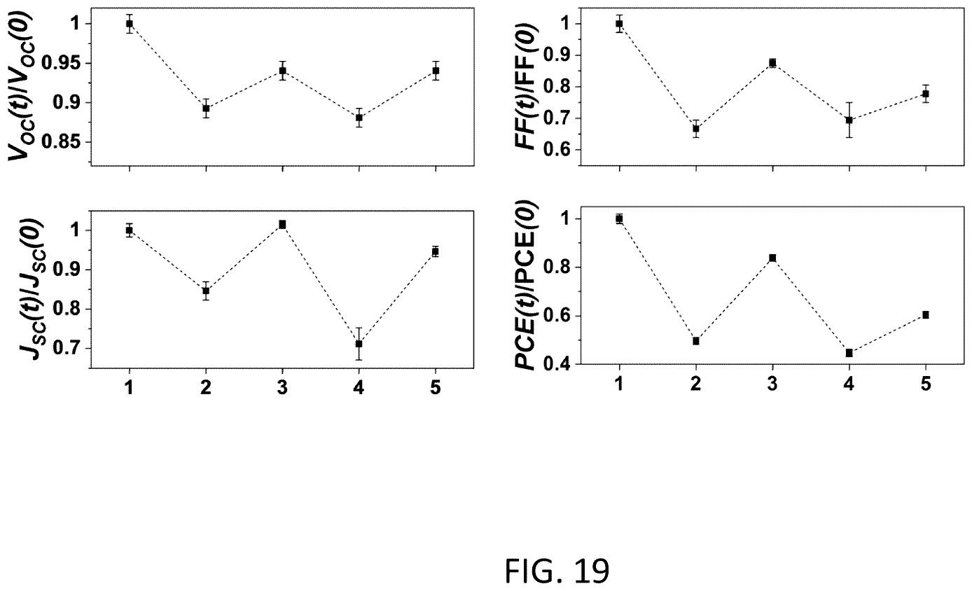

The devices can undergo multiple healing cycles after repeated irradiation (FIG. 19). The thermally annealed PM6:Y6 device was exposed to a second round of proton radiation with the same 30 keV energy fluence, followed by thermal annealing at same condition as before. Encouragingly, the V_{OC} and J_{SC} for the doubly irradiated PM6:Y6 device also rebounded to approximately 95% of the efficiency levels observed in the annealed, post-irradiation state. The FF again exhibited a 10% decrease. This suggests that the potential of OPVs for providing sustainable energy by self-repair capability.

Increased nonradiative recombination loss in proton irradiated devices, leads to a decrease in V_{OC}. Proton irradiation increases in electron traps of OPV devices. Thermal annealing can help re-healing these traps. To understand the effects of proton-radiation, EL can be used to understand the charge-transfer (CT) processes and charge recombination behavior in OPVs. Voc is related to EL efficiency. The EL intensity of the irradiated sample dropped significantly but recovered a little after thermal annealing, but not to the initial state. From the dark current, the ideality factor changes after proton irradiation. Based on the exponential distribution of traps as described by Giebink, the type of recombination is changing from trap-assisted recombination in Fresh device to Shockley-Read-Hall-type (SRH) recombination, which indicate the generation of new mid-gap traps by irradiation. When the devices undergo annealing, the n begin to recover to their original values, suggesting that the traps redistribute and recover their density of states under thermal annealing. Additionally, a shift of the J-V curve at J=0 by about 50 mV after irradiation. It is likely that the prolonged release of charge carriers from radiation induced trap states.

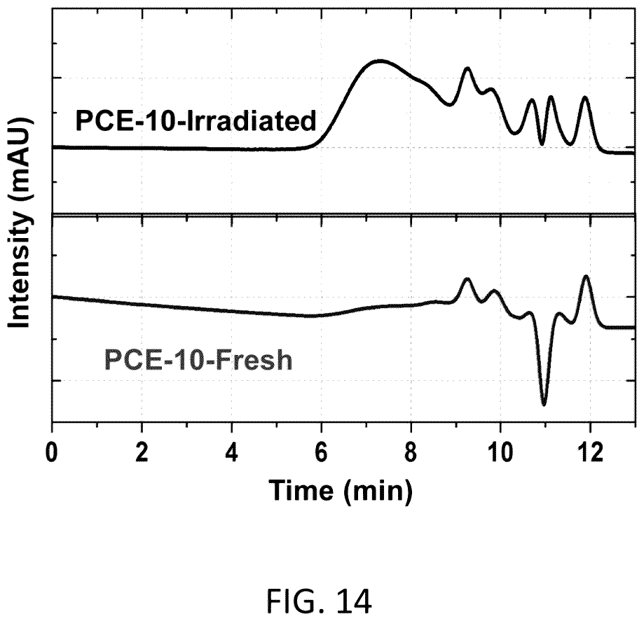

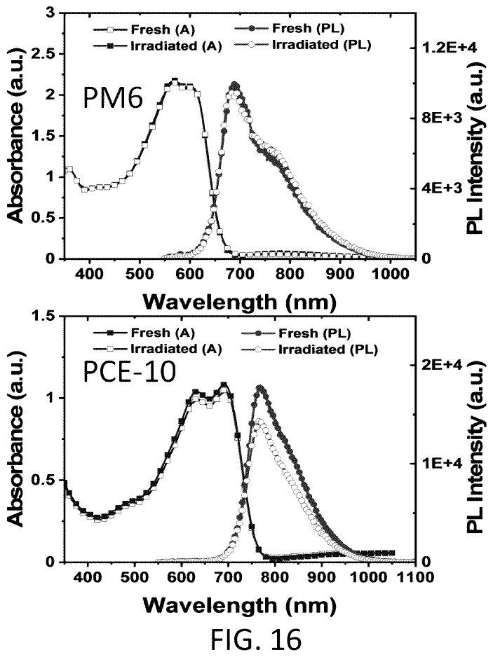

Gel permeation chromatography (GPC) scans in FIG. 14 indicate that the average molecular weight (M_{w}) of PCE-10 exposed to irradiation rises from 15,000 to 364,000, due to crosslinking. This is confirmed by the changes in the absorption spectra of the PCE-10:BT-CIC blend (see FIG. 16), indicating that PCE-10 retains its light absorption properties even after washing with chlorobenzene, a solvent that usually dissolves PCE-10. This behavior points to decreased solubility due to the formation of crosslinked polymer networks. A similar phenomenon is found in PM6:Y6 and other blends (see Parkhomenko, et al., Adv. Energy Mater., 2023 and Lee, et al., Sol. RRL, 2022.) Notably, the absorption and photoluminescence (PL) spectra of the PCE-10 and PM6 are unaffected by irradiation (see FIG. 16). The π-bonds within the aromatic rings participate in the light emission process. In contrast, alkyl chains are used as spacers and do not result in light emissions (see Zhang, et al., J. Am. Chem. Soc., 2017). This suggests that proton-induced chemical reactions predominantly occur at the alkyl chains, rather than in the aromatic rings comprising the backbone. As a result, the electronic chromophoric structures responsible for absorption and PL remain intact. Although proton-induced cross-linking has been found in both PM6 and PCE-10, insulating polyimides such as Kapton® and UPLEX® that do not contain alkyl chains, demonstrate exceptional radiation resistance (see Hatano, et al., TA-TT). This observation prompts the question as to whether small molecules that lack C—H side chains are more robust under irradiation than polymers with extensive side chains.

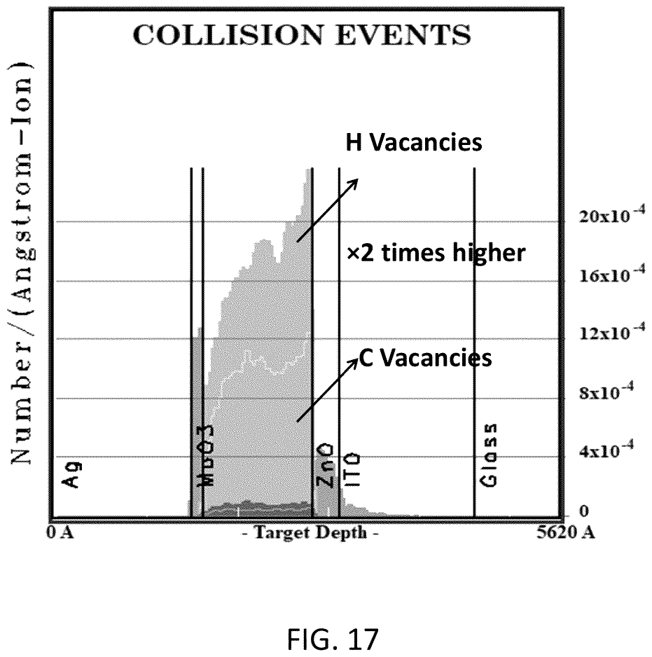

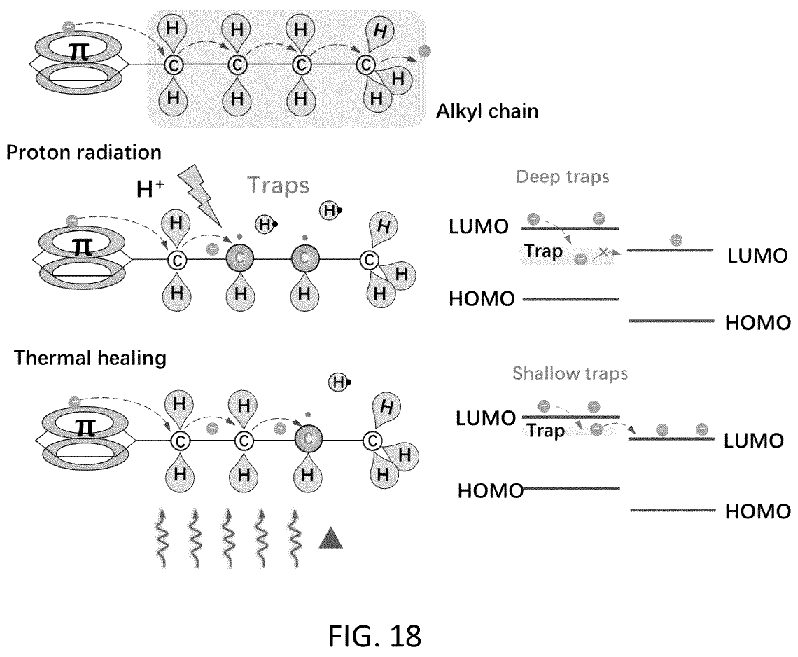

Previously, it has been shown that the alkyl chains are particularly susceptible to dissociation and creation of free radicals under radiation exposure (see Street, et al., Phys. Rev. B, 2012). The radical may attach to an adjacent carbon atom, resulting in over-coordinated carbon atoms, thereby generating localized states in the bandgap. To understand the degradation mechanism of polymer-based OPVs, simulations of the elemental vacancy profile were performed using SRIM. As shown in FIG. 17, H atoms (Magenta) are displaced in the BHJ by 30 keV protons, resulting in de-protonation. Consequently, this leads to the formation of a free radical defect, or H vacancy, where a carbon atom in the alkyl chain, which was previously fourfold coordinated, now has two C—C bonds and one C—H bond (see FIG. 18). It is likely that the resulting radical formation may promote polymer cross-linking, thereby forming mid-gap states responsible for recombination. Due to its low mass, the displaced H atom readily reattaches to the molecules by thermal annealing at temperatures>45° C. thus contributing to the recovery of PCE to nearly 90% of its value before irradiation (see Fru, et al., Radiat. Phys. Chem., 2024; Kirmani, et al., Nat. Commun., 2024; and Shang, et al., J. Mater. Chem. C, 2022). Moreover, small molecule OPVs containing few or no alkyl chains are not susceptible to this route to degradation, and hence show greater stability under proton irradiation.

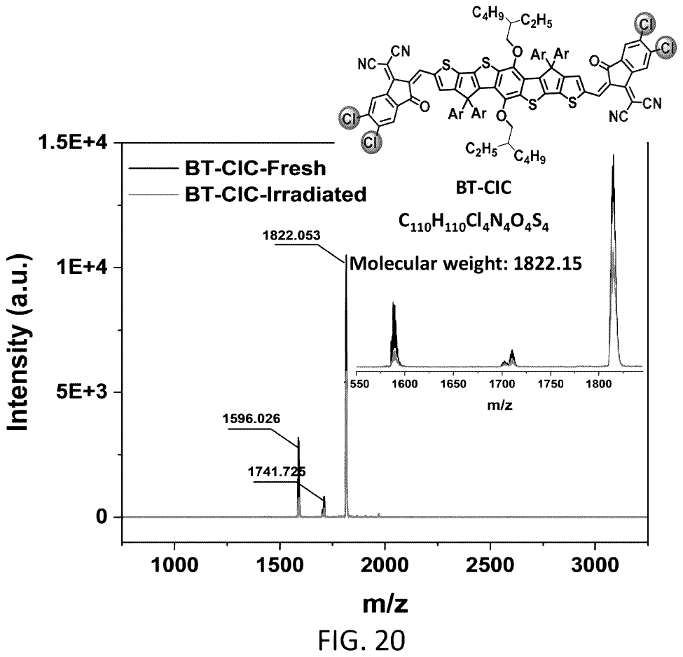

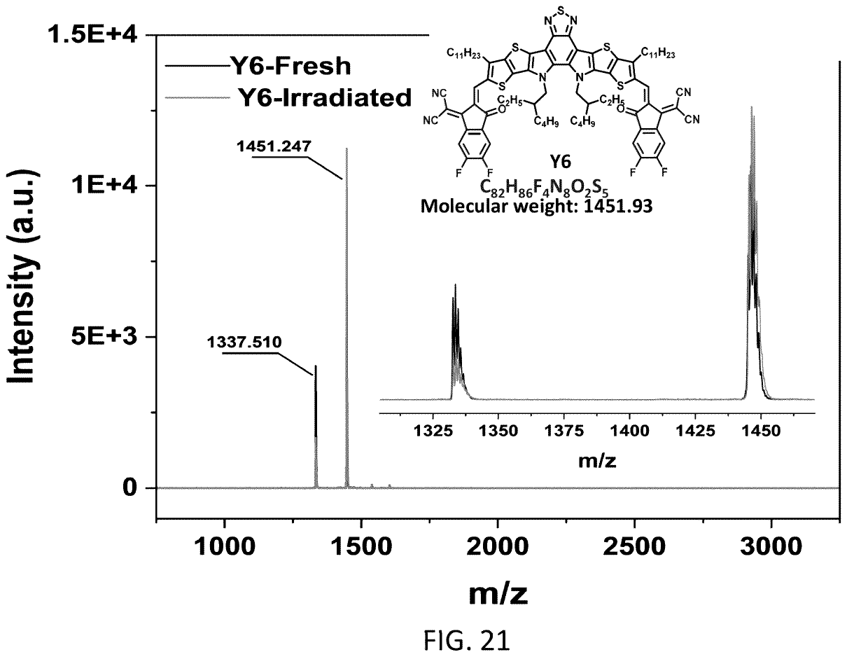

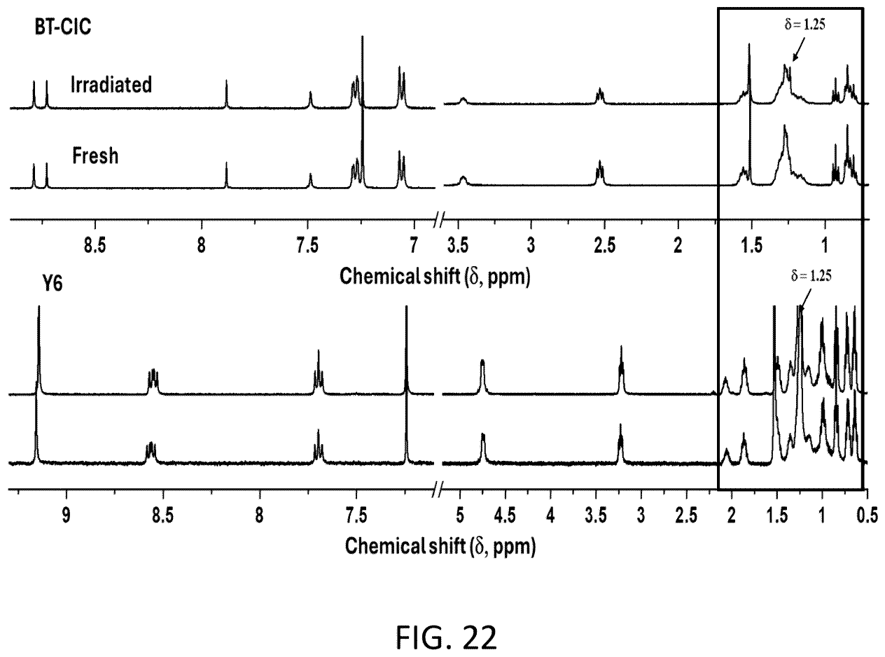

To evaluate the chemical stability of the BHJ components, matrix-assisted laser desorption ionization-time of flight mass spectrometry (MALDI-TOF-MS) and nuclear magnetic resonance (NMR) spectroscopy were employed to investigate the stability of BT-CIC and Y6 by identifying the resulting chemical fragments from proton bombardment. The MALDI-TOF-MS results are depicted in FIG. 20 and FIG. 21. The NMR results are shown in FIG. 22. No formation of new chemical species exhibiting mass lower than that of BT-CIC and Y6. A new peak at δ=1.25 ppm in the irradiated BT-CIC, which is characteristic of the saturated alkyl chain in the molecule. No new proton peaks or chemical shifts observed at the lower magnetic field.

To summarize a mechanism of degradation of OPV device after proton irradiation is proposed, and away to circumvent this damage is described. The hydrogen in the side chain of organic side chains results in traps, and these traps can be passivated by the migration of displaced hydrogen atoms via thermal annealing. OPVs exhibit considerable damage tolerance when irradiated by high proton fluences. Organic materials show different tolerance to proton radiation. VTE small molecules, particularly those without lengthy alkyl side chains, appear to demonstrate enhanced reliability in comparison to solution-processed materials with alkyl side chains. The OPVs have the capability to experience the multiple healing cycles and repeated irradiation exposure. The degradation of OPV device after proton bombardment is due to the traps generated in the BHJ. These traps arise because the hydrogen atoms in the side chains of organic molecules are kicked off. By combining these findings, the potential of OPV to be used as sustainable energy sources for space applications is clear.

It is understood that the various embodiments described herein are by way of example only, and are not intended to limit the scope of the disclosure. For example, many of the materials and structures described herein may be substituted with other materials and structures without deviating from the spirit of the disclosure. The present compounds as disclosed may therefore include variations from the particular examples and preferred embodiments described herein, as will be apparent to one of skill in the art. It is understood that various theories as to why the embodiments work are not intended to be limiting.

We claim:

1. A compound of Formula I, Formula II, Formula III, or Formula IV: 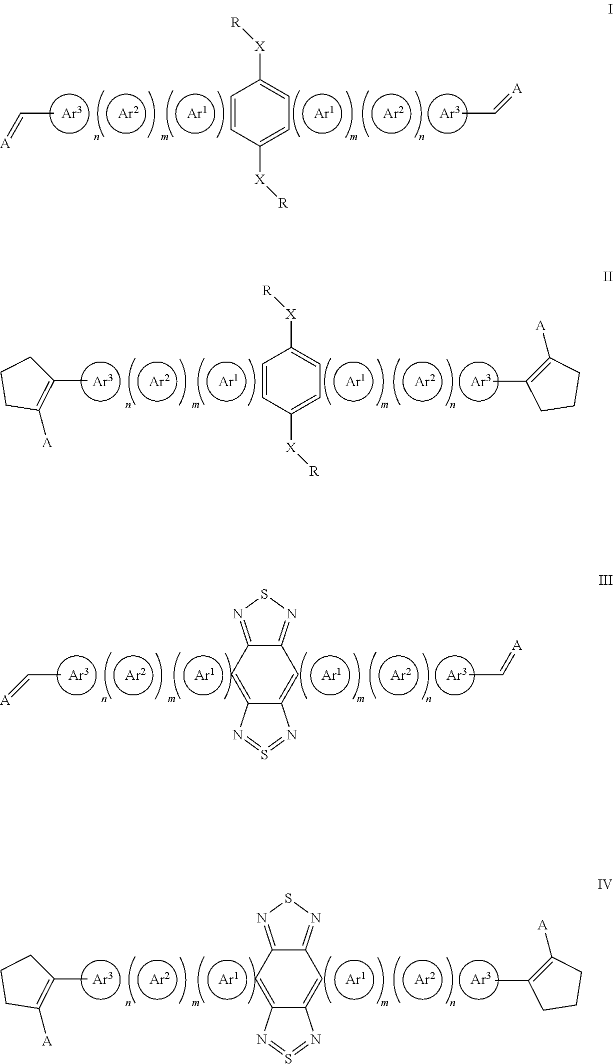
wherein
Ar¹ is an aromatic group, which is conjugated, fused, or connected to a benzene ring and is selected from the group consisting of: 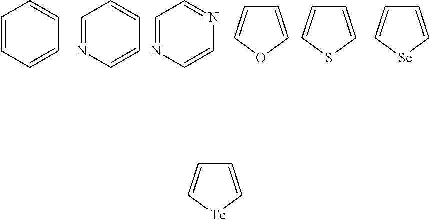
Ar² is an aromatic group, which is conjugated, fused, or connected to an Ar¹ ring, and is selected from the group consisting of: 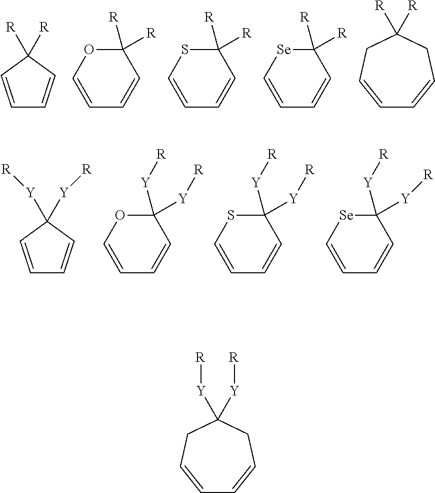
Ar³ is an aromatic group, which is conjugated, fused, or connected to an Ar² ring, is selected from the group consisting of: 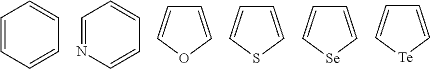
each X is independently selected from the group consisting of oxygen, sulfur, selenium, and nitrogen;
each R is independently an aromatic group;
m is from 0 to 10; and
n is from 0 to 10;
A is one of the following structures: 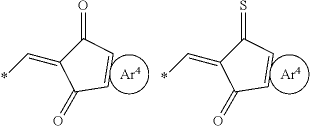 [SMILES: *C=C1C(=O)C=CC1=O ; */C=C1\C(=O)C=CC1=S]
Ar⁴ is an aromatic group, which is conjugated fused connected to an adjacent ring, and is selected from the group consisting of: 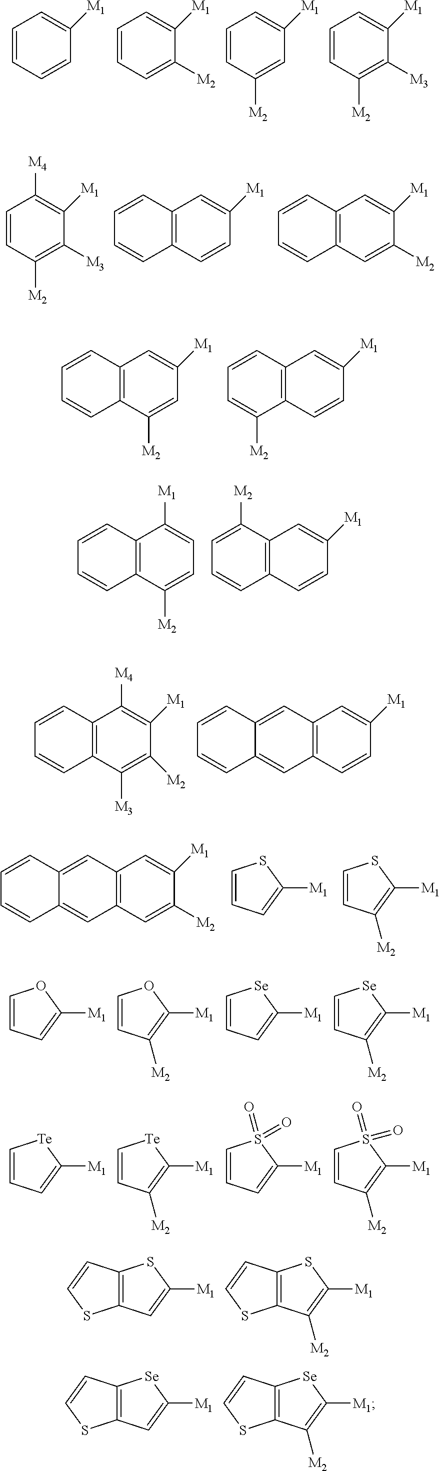
and
each M₁, M₂, M₃, and M₄ is independently selected from the group consisting of hydrogen, fluorine, chlorine, bromine, iodine, and cyano group, wherein at least one of M₁, M₂, M₃, and M₄ is a halogen.

2. The compound of claim 1, wherein the compound is represented by Formula I.

3. The compound of claim 1, wherein the compound is represented by Formula II.

4. The compound of claim 1, wherein the compound is represented by Formula III.

5. The compound of claim 1, wherein the compound is represented by Formula IV.

6. The compound of claim 1, wherein n and m are each 1.

7. The compound of claim 1, wherein R is selected from the group consisting of: 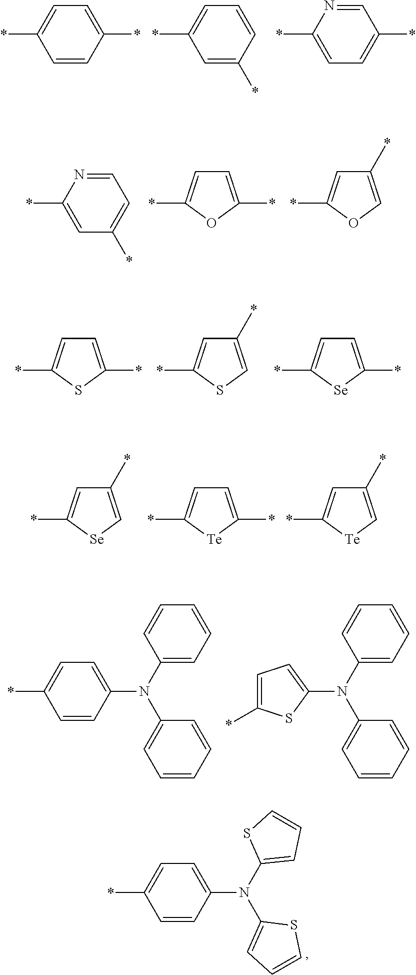
and combinations thereof.

8. The compound of claim 1, wherein A is

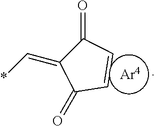 [SMILES: *C=C1C(=O)C=CC1=O]

9. The compound of claim 1, wherein Ar⁴ is one of the following structures:

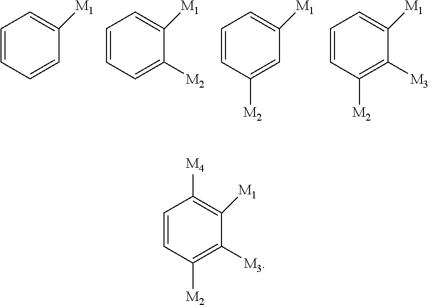

10. The compound of claim 1, wherein each of M₁, M₂, M₃, and M₄ represents Cl.

11. The compound of claim 1, wherein the compound is nonsymmetric.

12. The compound of claim 1, wherein the compound has no alkyl chains.

13. An optoelectronic device comprising a compound of Formula I, Formula II, Formula III, or Formula IV: 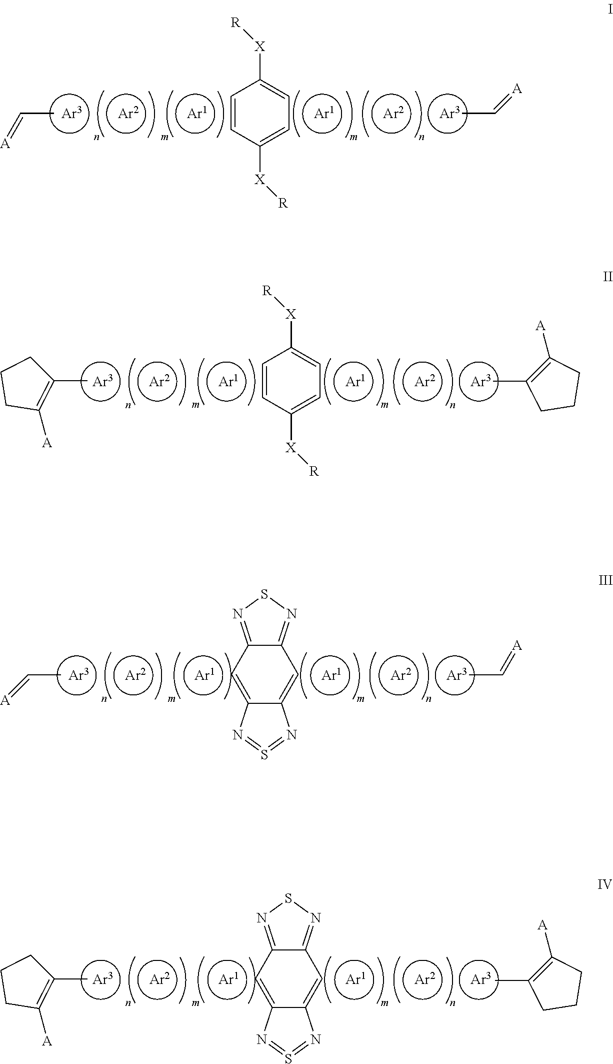
wherein:
Ar¹ is an aromatic group, which is conjugated, fused, or connected to a benzene ring and is selected from the group consisting of: 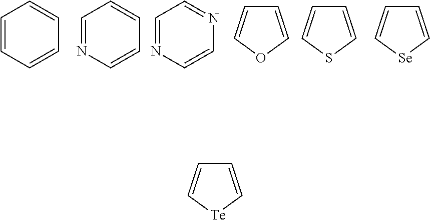
Ar² is an aromatic group, which is conjugated, fused, or connected to an Ar¹ ring, and is selected from the group consisting of: 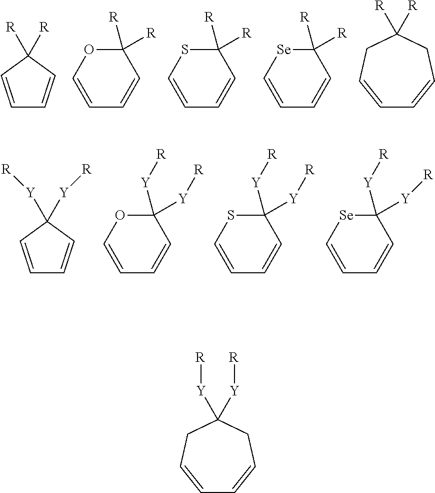
Ar³ is an aromatic group, which is conjugated, fused, or connected to an Ar² ring, is selected from the group consisting of: 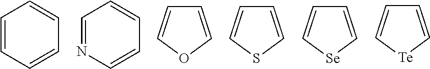
each X is independently selected from the group consisting of oxygen, sulfur, selenium, and nitrogen;
each R is independently an aromatic group;
m is from 0 to 10; and
n is from 0 to 10;
A is one of the following structures: 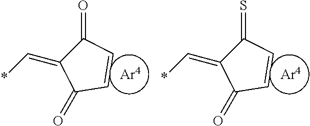 [SMILES: *C=C1C(=O)C=CC1=O ; */C=C1\C(=O)C=CC1=S]
Ar⁴ is an aromatic group, which is conjugated fused connected to an adjacent ring, and is selected from the group consisting of: 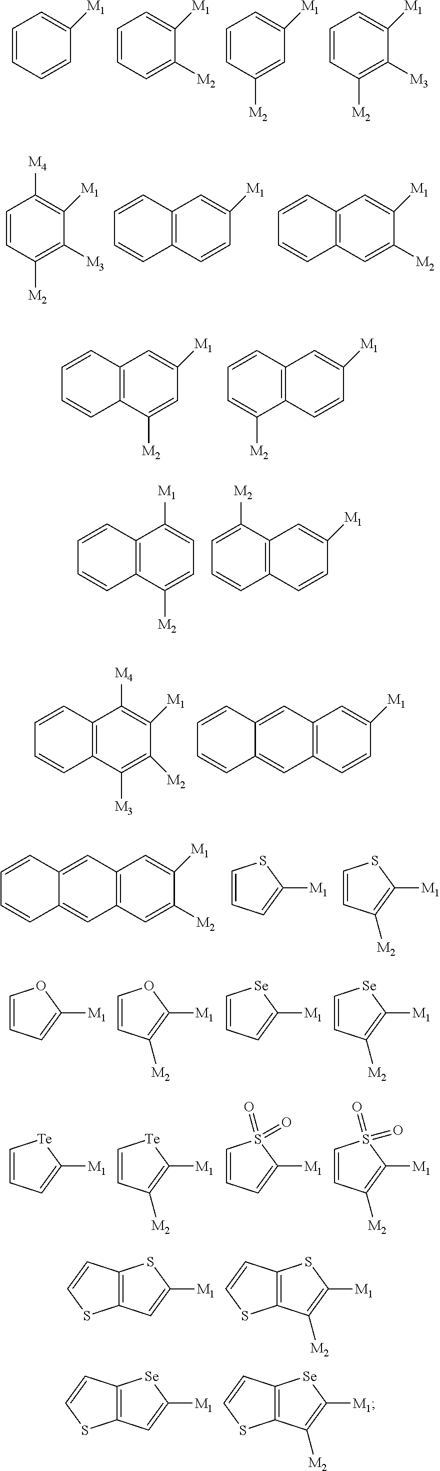
and
each M₁, M₂, M₃, and M₄ is independently selected from the group consisting of hydrogen, fluorine, chlorine, bromine, iodine, and cyano group, wherein at least one of M₁, M₂, M₃, and M₄ is a halogen.

15. A space-borne device comprising the optoelectronic device of claim 13.

16. A method of harvesting solar radiation, comprising the step of placing the optoelectronic device of claim 13 in outer space.
